(19) United States
(12) Patent Application Publication
(10) Pub. No.: US 2024/0013851 A1
(43) Pub. Date: Jan. 11, 2024

(54) DATA LINE (DQ) SPARING WITH ADAPTIVE ERROR CORRECTION CODING (ECC) MODE SWITCHING

(71) Applicant: Intel Corporation, Santa Clara, CA (US)

(72) Inventors: Hang CHEN, Shanghai (CN); Shen ZHOU, Shanghai (CN); Kuljit S. BAINS, Olympia, WA (US); Mohan J. KUMAR, Aloha, OR (US); Antonio J. HASBUN MARIN, San Antonio de Belen (CR)

(21) Appl. No.: 18/372,605

(22) Filed: Sep. 25, 2023

(30) Foreign Application Priority Data
Jun. 28, 2023 (WO) PCT/CN2023/103032

(51) Int. Cl. G11C 29/52; G11C 29/00; G11C 11/406

(52) U.S. Cl. CPC G11C 29/52; G11C 29/883; G11C 11/40618

(57) ABSTRACT

A system provides DO-level sparing to spare a fault of a data signal (DQ) line of a memory bus. The data bus has multiple data dynamic random access memory (DRAM) devices and at least one error correction code (ECC) DRAM device coupled to it. An error manager can be in the memory controller or in a platform error controller. The error manager to detect a DQ failure and dynamically switches ECC mode on the fly. The error manager can map out data bits of the DQ and remap ECC bits of the at least one ECC DRAM device to the mapped out data bits of the DQ.

### CLAIM OF PRIORITY

The present application claims the benefit of priority to Patent Cooperation Treaty (PCT) Application No. PCT/CN2023/103032, filed Jun. 28, 2023, the entire content of which is incorporated herein by reference.

### TECHNICAL FIELD

Descriptions are generally related to memory systems, and more particular descriptions are related to memory sparing.

### BACKGROUND OF THE INVENTION

Memory error is one of the main errors that causes server downtime in the modern datacenter. With the error correction coding (ECC), memory errors can be classified into two categories: 1) correctable error (CE), which refers to an error correctable by ECC, which therefore does not have a severe consequence, and 2) uncorrectable error (UE), which refers to an error unable to be corrected by ECC (e.g., a single-device UE) or not in the coverage of ECC (e.g., a multidevice UE), which causes workload failure or server downtime.

A DQ failure can impact a large range of memory and may flip bits across multiple banks and bank groups, which is one of the major memory fault modes causing UEs in current memory devices. Based on certain testing/validation data, DQ failures can be the top cause of UEs in some memory systems.

To avoid UEs, systems use sparing techniques to allow on-the-fly failover from a failing component to another component. Modern sparing techniques can spare failed memory at different levels, including nibble level sparing by partial cacheline sparing (PCLS), row level sparing by post package repair (PPR), bank sparing by adaptive double device data correction (ADDDC), and other sparing techniques.

In row sparing (e.g., PPR), if the platform or operating system (OS) discovers a memory row having a defect (one or more defective bits) during system operation, the system can trigger the setting of a fuse in the memory device to map a spare row into the array to replace the defective row. With row sparing, the system maps the defective row out of the memory array, excluding it from use.

A bank sparing technique, such as ADDDC, can map out a bank of a memory device (e.g., a bank of the physical memory chip) having hard errors by putting the failing memory region into a virtual lockstep mode. It will be understood that bank sparing has been used to spare a bitline/data signal (DQ) failure but sparing the bank for a failed bitline impacts a much larger memory region than the failure. Thus, bank sparing for failure of a single bitline has a significant negative impact as it severely reduces the total available memory capacity relative to the failure. ADDDC can have a significant runtime performance impact. Thus, bank sparing either has a significant performance impact or requires a system reboot.

PCLS is a sparing technique that detects a single-bit or single-nibble hard error within a cacheline and then replaces the entire nibble (e.g., 4-bits) within the spare capacity in the central processing unit (CPU). For example, an integrated memory controller (iMC) of the CPU can implement the PCLS.

Row sparing (e.g., PPR), nibble sparing (e.g., PCLS), and page offlining cannot provide the sparing coverage for a bitline/DQ failure. While bank sparing (e.g., ADDDC) can provide sparing coverage for a bitline/DQ, the performance and/or capacity impact is significant.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with DQ sparing.

FIG. 2A is a block diagram of an example of a memory subsystem for DQ sparing.

FIG. 2B is a block diagram of an example of a memory device input/output architecture.

FIG. 3 is a block diagram of an example of DQ sparing control architecture.

FIG. 4 is a block diagram of an example of a system architecture for DQ sparing.

FIG. 5 is a block diagram of an example of a system in which a controller maintains a defective DQ directory.

FIG. 6A is a block diagram of an example of uncorrectable error analysis training.

FIG. 6B is a block diagram of an example of sparing based on uncorrectable error analysis.

FIG. 7 is a block diagram of an example of a system that reduces ECC and remaps fora failed DQ.

FIG. 8A is a block diagram of an example of a system that reduces ECC and remaps fora failed DQ.

FIG. 8B is a block diagram of an example of a system that reduces ECC and remaps for two failed DQs.

FIG. 9 is a block diagram of an example of a system that reduces ECC and remaps for three failed DQs.

FIG. 10 is a block diagram of an example of a data read/write flow with DQ sparing.

FIG. 11 is a flow diagram of an example of a process for DQ sparing.

FIG. 12 is a block diagram of an example of a memory subsystem in which DQ sparing can be implemented.

FIGS. 13A-13B are block diagrams of an example of a CAMM system in which DQ sparing can be implemented.

FIG. 14 is a block diagram of an example of a computing system in which DQ sparing can be implemented.

FIG. 15 is a block diagram of an example of a multi-node network in which DQ sparing can be implemented.

Descriptions of certain details and implementations follow, including non-limiting descriptions of the figures, which may depict some or all examples, and well as other potential implementations.

### DETAILED DESCRIPTION OF THE INVENTION

As described herein, a system provides DO-level sparing to spare a fault of a data signal (DQ) line of a memory bus. The data bus has multiple data dynamic random access memory (DRAM) devices and at least one error correction code (ECC) DRAM device coupled to it. An error manager can be in the memory controller, in a platform error controller, or spread between the memory controller and the platform error controller. The error manager can detect a DQ failure and dynamically switch ECC mode on the fly. The error manager can map out data bits of the DQ and remap ECC bits of the at least one ECC DRAM device to the mapped out data bits of the DQ.

The memory subsystem can include DQ fault management to enable DQ sparing with dynamic switching of the ECC mode. Lowering the ECC mode means that fewer ECC bits are needed to implement ECC, which frees up bits in the memory. The DQ fault management can remap the freed-up ECC bits, repurposing them for use as data bits to take the place of the data bits from the spared-out DQ.

The system can perform the ECC downgrade and repurpose the bits on-the-fly during runtime of the memory subsystem. Since DQ faults significantly increase the correctable error (CE) number for each unit of the data burst, as well as increasing the risk of multidevice uncorrectable error (UE), incorporating the dynamic DQ sparing capability into a server platform improves the reliability, availability, and serviceability (RAS) of a server system. A system with the features described can avoid UEs that result from DQ faults.

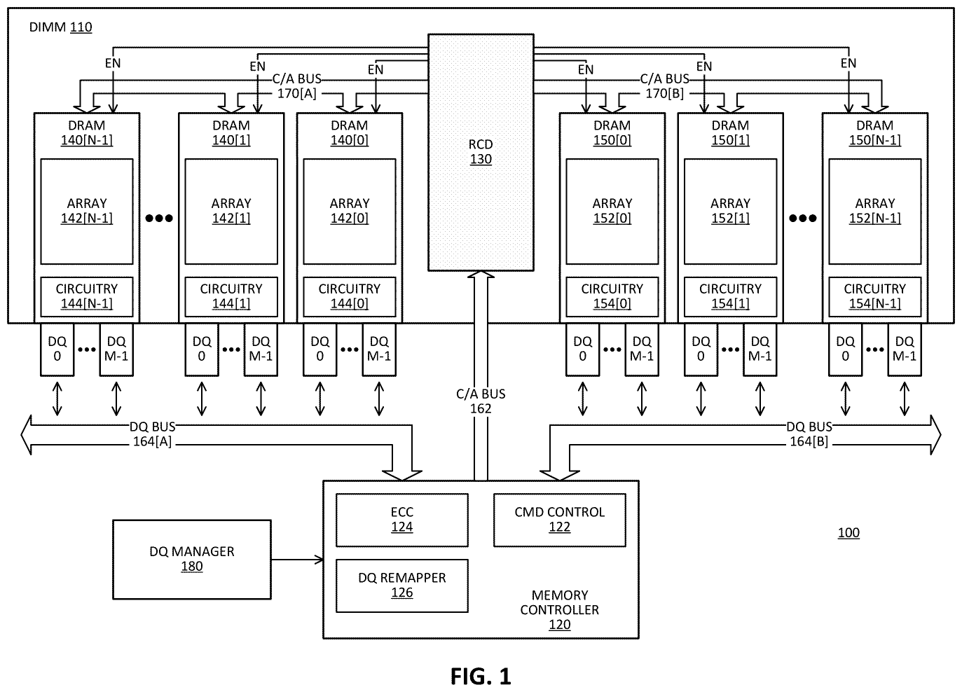

FIG. 1 is a block diagram of an example of a system with DQ sparing. System 100 illustrates memory coupled to a host. Dual inline memory module (DIMM) 110 represents a memory module that includes multiple memory devices, illustrated by DRAM devices 140[0:(N−1)], or collectively, DRAM devices 140 and DRAM devices 150[0:(N−1)], or collectively, DRAM devices 150. N can be any integer greater than 2, with at least one ECC device.

Memory controller 120 represents the host, which can be part of a computing platform, such as a central processing unit (CPU) system on a chip (SOC) or other host processing element SOC, such as a graphics processing unit (GPU). Memory controller 120 includes hardware interconnects and driver/receiver hardware to provide the interconnection between memory controller 120 and DIMM 110. While DIMM 110 provides one example of a module with multiple memory devices, system 100 could alternatively be applied with a high bandwidth memory (HBM) package having multiple DRAM chips in a vertical stack.

System 100 illustrates one example of DIMM 110 with registered (or registering) clock driver (RCD) 130 and memory devices. RCD 130 represents a controller for DIMM 110. In one example, RCD 130 receives information over command/address (C/A) bus 162 from memory controller 120 and buffers the signals to the memory devices over C/A buses. System 100 represents two separate channels on DIMM 110, where each channel can have one or more ranks of DRAM devices. A rank refers to a group of DRAM devices that are accessed by a common chip select signal.

C/A bus 170[A] can be a first channel (Channel A) for DRAM devices 140. C/A bus 170[B] can be a second channel (Channel B) for DRAM devices 150. System 100 also illustrates enable lines (EN) from RCD 130 to the various DRAM devices. C/A bus 170[A] and C/A bus 170[B] can collectively be referred to as C/A buses 170. C/A buses 170 represent buses to provide command encoding and address information for a memory access operation. C/A buses 170 are typically unilateral buses or unidirectional buses to carry command, address, and enable information from RCD 130 to the DRAM devices in response to a command from memory controller 120.

Data (DQ) bus 164[A] represents a bus to exchange data between DRAM devices 140 and memory controller 120, and data (DQ) bus 164[B] represents a bus to exchange data between DRAM devices 150 and memory controller 120. DQ bus 164[A] and DQ bus 164[B] can collectively be referred to as DQ buses 164. DQ buses 164 are traditionally bidirectional, point-to-point buses.

DRAM devices 140[0:(N−1)] respectively include array 142[0:(N−1)], collectively, arrays 142. Arrays 142 store data from DQ bus 164[A] in response to a write command, and provide data to DQ bus 164[A] in response to a read command. DRAM devices 140[0:(N−1)] respectively include circuitry 144[0:(N−1)], collectively, circuitry 144. Circuitry 144 represents circuitry that interfaces arrays 142 to store data from DQ bus 164[A] in response to a write command, and provide data to DQ bus 164[A] in response to a read command.

DRAM devices 150[0:(N−1)] respectively include array 152[0:(N−1)], collectively, arrays 152. Arrays 152 store data from data bus 164[B] in response to a write command, and provide data to data bus 164[B] in response to a read command. DRAM devices 150[0:(N−1)] respectively include circuitry 154[0:(N−1)], collectively, circuitry 154. Circuitry 154 represents circuitry that interfaces arrays 152 to store data from DQ bus 164[B] in response to a write command, and provide data to DQ bus 164[B] in response to a read command.

DRAM devices 140 and DRAM device 150 are illustrated as having a xM interface, with M data bus pins, DQ[0:(M−1)]. M can be any integer and is typically a binary integer such as 4, 8, or 16. Each DQ interface will transmit data bits over a burst length (BL), such as BL16 for a 16 unit interval or transfer cycle data exchange. Thus, the data transfer is BL×M, such as a ×4 interface (e.g., M=4) with BL16 (e.g., 16 unit intervals (UIs) of transfer) for 4×16=64 bits per device.

Memory controller 120 receives read data on a DQ bus or sends data on a DQ bus corresponding to a command sent on C/A (command/address) bus 162. The command sent on C/A bus 162 includes command encoding and address information. In one example, C/A bus 162 connects memory controller 120 to RCD 130, where memory controller 120 can send commands to either channel, and RCD 130 generates command and enable signals on DIMM 110. For Channel A, RCD 130 can provide command and address information on C/A bus 170[A] to DRAM devices 140. For Channel B, RCD 130 can provide command and address information on C/A bus 170[B] to DRAM devices 150. RCD 130 asserts the enable (EN) signal lines for the desired DRAM devices associated with an access command.

Memory controller 120 includes command (CMD) control 122, which represents logic at memory controller 120 to send commands to the DRAM devices. In one example, memory controller 120 includes error checking and correction (ECC, or error correction coding) 124 to identify and correct data errors in data received from the DRAM devices.

In one example, memory controller 120 includes DQ remapper 126. In response to an error in a specific DQ of one of the memory channels, memory controller 120 can spare the DQ, reduce the ECC applied by ECC 124, and remap the data bits from the DQ to the ECC bits freed by reducing the ECC applied.

In one example, system 100 includes DQ manager 180. In one example, DQ manager 180 is part of memory controller 120. In one example, DQ manager 180 is implemented as firmware on memory controller 120. In one example, DQ manager 180 is separate from memory controller 120. In one example where DQ manager 180 is separate from memory controller 120, the DQ manager can be part of a controller circuit that monitors errors in system 100. Such a controller circuit can be disposed on a substrate as part of a chip separate from the memory controller. The circuit can be coupled to the memory controller or coupled directly to the memory bus to detect errors. In one example, DQ manager 180 is implemented as firmware on the error detector controller. More details of such a controller are provided in reference to subsequent drawings.

In one example, DQ manager 180 determines that a DQ in system 100 has experienced an uncorrectable error (UE) and determines to spare out the failed DQ. Based on such a determination, DQ manager 180 can trigger ECC 124 to reduce the level of ECC applied. The reduction of ECC refers to dynamically switching ECC to a lower coverage mode. Reducing the level of ECC applied will free up bits that were previously used for ECC. The determination to spare the failed DQ and the reduction of ECC can occur on-the-fly. DQ remapper 126 enables memory controller 120 to repurpose the freed up ECC bits to store the data from the retired/spared DQ.

In one example, DQ remapper 126 is part of DQ manager 180. When DQ manager 180 is part of memory controller 120, DQ remapper 126 can be a part of both memory controller 120 and DQ manager 180. When DQ manager 180 is separate from memory controller 120, DQ remapper 126 can be considered a distributed component of DQ manager 180 located in memory controller 120 to enable the remapping of data bits from the DQs in the system.

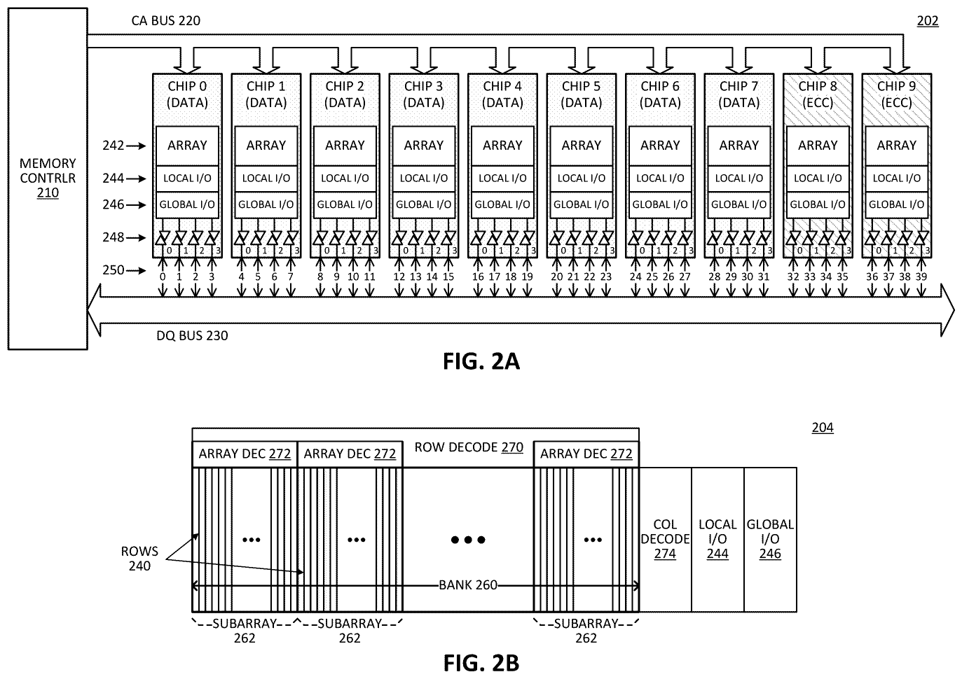

FIG. 2A is a block diagram of an example of a memory subsystem for DQ sparing. System 202 represents a memory subsystem in accordance with an example of system 100. System 202 illustrates memory controller (CONTRLR) 210 coupled to ten (10) dynamic random access memory (DRAM) devices. System 202 more specifically illustrates the memory devices as chips [0:9], where each chip is a separate DRAM device.

Command/address (CA) bus 220 represents a command bus over which memory controller 210 can provide command encoding and address information to the DRAM devices. CA bus 220 represents a unidirectional bus to provide information from memory controller 210 to the DRAM devices. Data (DQ) bus 230 represents a data bus to exchange data between the DRAM devices and memory controller 210, where memory controller 210 drives data on DQ bus 230 for a write operation, and the DRAM devices drive data on DQ bus 230 for a read operation.

As illustrated, chip[0:7] represent data devices, to store user data, and chip[8:9] represent ECC devices, to store system ECC information. It will be understood that each of the DRAM devices could optionally include on-die ECC, where an ECC circuit on the die generates and stores ECC bits internally to detect and correct errors in data provided to memory controller 210. Such ECC information can be referred to as internal ECC bits. Internal ECC bits are generated and applied only locally at an individual device.

The ECC information stored in chip[8:9] refers to system ECC, which is ECC applied by memory controller 210 on the data received collectively from the data devices. System ECC information is generated and applied by memory controller 210 on data stored across chip[0:7]. On a write operation, memory controller 210 generates and writes the ECC data to be stored in chip[8:9] in parallel with the data stored in chip[0:7]. For a read operation, each DRAM device provides its data to memory controller 210, which knows the mapping of the data.

As illustrated, each DRAM device includes array 242, which represents the storage array that stores the data in the chip. The DRAM devices include local input/output (I/O) 244 and global input/output (I/O) 246. Local I/O 244 provides interface circuitry to local subsections of array 242. Global I/O 246 interconnects the various subsections to transceiver circuits 248 that interface with the DQ lines of DQ bus 230.

Transceiver circuits 248 can map specific data pathways to specific ones of I/O pins 250 on the chip. As illustrated, chip[0:9] are ×4 devices, referring to having four (4) I/O pins to the DQ bus. Other devices can be ×8, ×16, or other interface width. System 202 illustrates internal I/O counts for transceiver circuits 248 of each device as 0, 1, 2, and 3, referring to the four I/O pins for each chip. System 202 illustrates I/O pins 0, 1, 2, 3, 4, 5, . . . , 38, 39, referring to the total DQ pin interface from the collective DRAM devices to DQ bus 230. The numbering is for convenience in description as identified below.

With eight (8) data devices and two (2) ECC devices, system 202 can apply various levels of ECC at the system level. Reference to applying different levels of ECC will be understood throughout as referring to the application of system ECC.

Different ECC modes that system 202 can apply include 1) 10×4, 128-bit (or 125-bit) ECC mode; 2) 10×4, 96-bit ECC mode; 3) 9×4, 64-bit ECC mode. Mode 1 refers to the use of 8 data devices and 2 ECC devices, with 128 bits or 125 bits of ECC information stored in the 2 ECC devices. Mode 2 refers to the use of 8 data devices and 2 ECC devices, with 96 bits of ECC information stored in the 2 ECC devices. Mode 3 refers to the use of 8 data devices and 1 ECC device, with 64 bits of ECC information stored in the ECC device.

In one example, system 202 can perform runtime ECC mode changes, changing the level of system ECC applied on-the-fly. Reducing the ECC level frees bits, which the system can then repurpose for a failed DQ. Memory controller 210 can remap how it interprets the bits received from the various DRAM devices, including ignoring bits from the failed DQ and remapping bits from one or more ECC device as data bits for the failed DQ. In one example, memory controller 210 maps all bits of a failed DQ to a single ECC device. In one example, memory controller 210 maps the bits of a failed DQ to multiple ECC devices.

Assume system 202 is an application of a 10×4 double data rate version 5 (DDR5) DIMM with 128 bits ECC mode in which a DQ failure is detected. In one example, system 202 can spare up to 2 failed DQs (16 bits per DQ in DDR5, 2 DQ=32 bits) by changing ECC mode from 128-bit ECC to 96-bit ECC and repurposing the freed 32-bits from an ECC device to store the data from spared DQ(s). In one example, system 202 could spare up to 4 failed DQs by switching ECC from 10×4 128-bit ECC mode to 9×4 64-bit ECC mode and repurposing the released 64-bits to store the data from spared DQs.

FIG. 2B is a block diagram of an example of a memory device input/output architecture. Memory 204 illustrates components of a DRAM device with a specific mapping of I/O to portions of the memory array, in accordance with any example of system 202.

Memory 204 includes bank 260, which includes multiple rows of memory cells. The vertical rectangles of the diagram represent the rows. In one example, bank 260 is organized as multiple subarrays 262. Subarray 262 or an array can refer to a group of rows 240. An access command (either a Read command or a Write command) triggers command signal lines that are interpreted by row decode 270 to select a row or rows for the operation. In one example, row decode 270 includes subarray or array decode (DEC) 272 to select a specific subarray 262 of bank 260.

Memory 204 includes column decode 274 to select a column of data, where signal lines from specific subarrays can be output to sense amplifiers and routed with local I/O 244 to global I/O 246. In one example, column (COL) decode 274 includes multiplexers to selectively connect certain columns to a common I/O connector. Local I/O 244 refers to the routing circuitry to transfer data of specific subarrays 262. Global I/O 246 refers to the routing circuitry that couples the local I/O to the external I/O connectors (I/O pins) of memory 204.

In one example, local I/O 244 includes logic to map specific signal lines from subarrays 262 to specific I/O paths or data paths that connect to specific global I/O connectors. Data paths can include wires and circuits to switch or select the paths to connect memory cells to the I/O for the device. Data paths can refer to the wires, traces, logic gates, and other circuitry to transfer data between the subarrays and the I/O. Data paths can refer to all connection logic and I/O logic to couple the data array to the external-facing connector or pad for the device package.

It will be understood that any portion of the I/O can experience a failure. A failure in column decode 274 can result in a DQ failure by interrupting a data path to an I/O connector. A failure in local I/O 244 can also result in a DQ failure by interrupting a data path to an I/O connector. A failure in global I/O 246 can also result in a DQ failure by interrupting a data path to an I/O connector. A failure in the data path at any level resulting in a DQ failure can be addressed by DQ sparing as described above with reference to system 202.

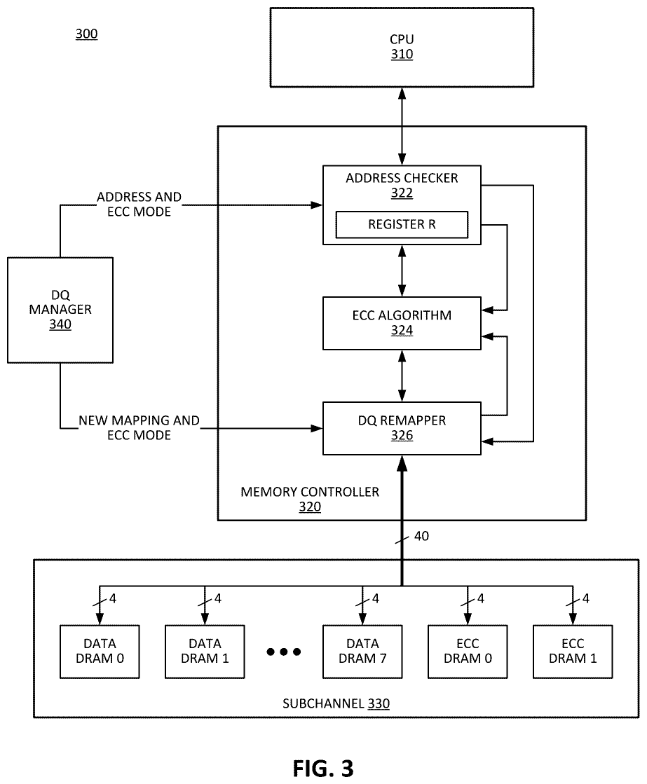

FIG. 3 is a block diagram of an example of DQ sparing control architecture. System 300 illustrates a system in accordance with an example of system 100 or system 202. System 300 illustrates the logical location of components of DQ management, including the DQ manager, address checker, and DQ remapper.

System 300 illustrates central processing unit (CPU) 310, which represents a processing unit that generates memory access requests for the memory represented by subchannel 330. Subchannel 330 includes data DRAM 0, data DRAM 1, . . . , and data DRAM 7, as well as ECC DRAM 0 and ECC DRAM 1, for a total of 10 DRAM devices. As illustrated, each DRAM device has a ×4 interface, for a total of 40 DQ signal lines to interface with memory controller 320.

Memory controller 320 manages access to subchannel 330. In one example, memory controller 320 is part of CPU 310. System 300 does not illustrate all details of memory controller 320. In one example, memory controller 320 includes address checker 322, which can optionally include Register R, ECC algorithm 324, and DQ remapper 326. ECC algorithm 324 represents the system ECC executed by memory controller 320. Address checker 322 can identify if reads or writes are directed to a spared region. DQ remapper 326 enables memory controller 320 to determine how to receive and how to send data without using spared regions.

System 300 includes DQ manager 340, which represents a component that manages DQ sparing for system 300. In one example, DQ manager 340 is within memory controller 320. In one example, DQ manager 340 is implemented as firmware of memory controller 320. In one example, DQ manager 340 is a state machine or a hardware component of memory controller 320. In one example, DQ manager 340 is separate from memory controller 320, such as part of a chipset or a system error manager. When DQ manager 340 is separate from memory controller 320, it can be implemented as hardware or firmware of another host component.

DQ manager 340 can include the DQ sparing result for each bank of subchannel 330. DQ manager 340 can manage the corresponding ECC modes associated with the DQ sparing results. In one example, DQ manager 340 represents a microcontroller or firmware logic executing on a microcontroller. DQ manager 340 can read the memory subsystem information (e.g., configuration) and record DIMM configurations and ECC mode information.

In one example, a microcontroller, firmware, or software of system 300 notifies DQ manager 340 of a DQ fault. The microcontroller can be an error detector controller. The firmware can be firmware of memory controller 320 or another platform component. The software can be software executed on CPU 310, such as the host operating system (OS).

In response to a DQ fault, in one example, DQ manager 340 checks the feasibility of sparing the DQ. If the DQ fault can be spared, address checker 322 can determine whether a read/write operation is in the spared DQ location. DQ remapper 326 can reorder the DQ bits from the spared DQ to freed-up ECC bit space, to store and read data to/from the freed location.

Before DQ sparing, DQ remapper 326 and address checker 322 can be transparent to read and write operations, allowing reads and writes to be executed as normal. Once a DQ sparing is inferred, DQ manager 340 can notify address checker 322 and DQ remapper 326 of the sparing. The cachelines in the corresponding bank should be refreshed with a new ECC mode. System 300 can refresh the bank that contains a DQ fault with one of two actions. For fast and immediate action, memory controller 320 can hold the read and write request from/to the bank related to the DQ fault until all cachelines of the bank are refreshed.

An alternative action is to refresh the bank during memory controller idle time. In one example, Register R provides a mechanism for address checker 322 to log the refreshing status in a bank. When system 300 starts refreshing, Register R can be initialized with the lowest address in the bank. During system idle time, which includes bank idle time when the bank is not being accessed, the address checker 322 can refresh the cacheline from Register R to the higher address and increment Register R to the new address. In one example, address checker 322 stops refresh once memory controller 320 is busy. If a read/write operation accesses a location in the bank during refresh, address checker 322 can compare the operation address with what is stored in Register R. If the operation accesses a location that has a lower address than Register R, in one example, address checker 322 applies the new mapping; otherwise, address checker 322 applies the old mapping.

As mentioned above, DQ manager 340 can manage the ECC mode applied to subchannel 330. In one example, system 300 can dynamically switch ECC mode from a 10×4 128-bit ECC mode to a 10×4 96-bit ECC mode. In one example, after DQ manager 340 has already switched ECC mode to a 10×4 96-bit ECC mode, system 300 can subsequently dynamically switch ECC mode to a 9×4 64-bit ECC mode. In one example, system 300 can dynamically switch ECC mode from a 10×4 128-bit ECC mode to a 9×4 64-bit ECC mode without first switching to a 10×4 96-bit mode.

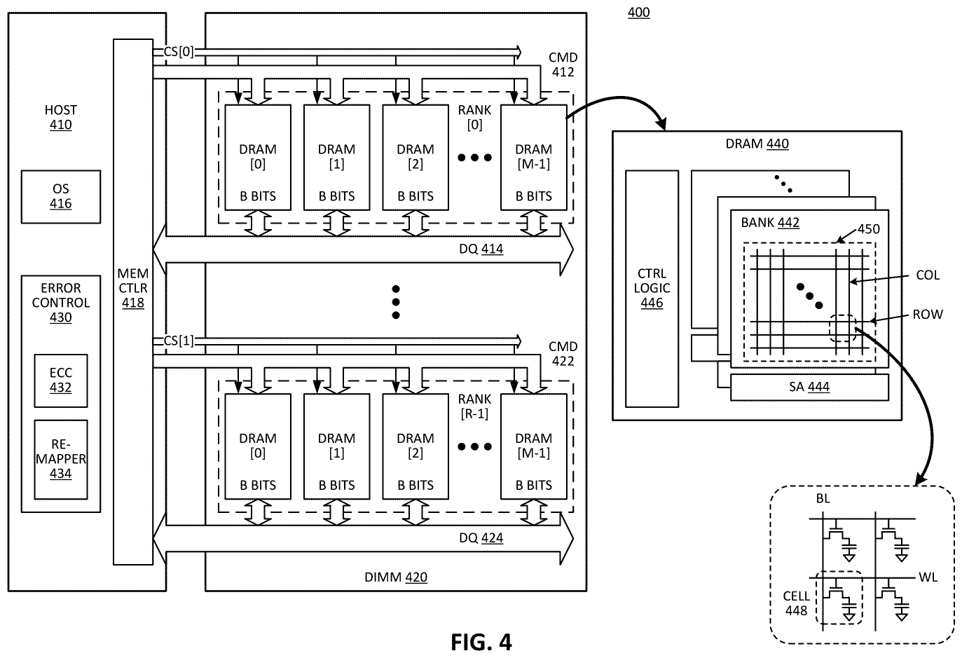

FIG. 4 is a block diagram of an example of a system architecture for DQ sparing. System 400 illustrates a computer system in accordance with an example of system 100 or an example of system 202. System 400 includes host 410 connected to DIMM 420. Host 410 represents the host hardware platform for the system in which DIMM 420 operates. Host 410 includes a host processor (not explicitly shown) such as a CPU or GPU to execute operations that request access to memory of DIMM 420.

DIMM 420 includes DRAM devices or DRAMs connected in parallel to process access commands. DIMM 420 is more specifically illustrated as a two-rank DIMM, with M DRAMs (DRAM[0:M−1]) in each rank, Rank 0 and Rank 1. M can be any integer. Typically, a rank of DRAMs includes data DRAMs to store user data and ECC DRAMs to store system ECC bits and metadata. System 400 does not distinguish DRAM purpose. In one example, the DRAM devices of system 400 represent DRAM devices compatible with a double data rate version 5 (DDR5) standard from JEDEC (Joint Electron Device Engineering Council, now the JEDEC Solid State Technology Association).

The DRAMs of a rank share a command bus and chip select signal lines, and have individual data bus interfaces. Command (CMD) 412 represents the CA bus for Rank 0 and command (CMD) 422 represents the CA bus for Rank 1. CS0 represents a chip select for the devices of Rank 0 and CS1 represents the chip select for the devices of Rank 1. DQ 414 represents the data (DQ) bus for the devices of Rank 0, where each DRAM contributes B bits, where B is an integer, for a total of B*M bits on the DQ bus. DQ 424 represents the data (DQ) bus for the devices of Rank 1.

DRAM 440 provides a representation of an example of details for each DRAM device of system 400. DRAM 440 includes control (CTRL) logic 446, which represents logic to receive and decode commands. Control logic 446 provides internal control signals to respond to commands received on the command bus. DRAM 440 includes multiple banks 442, where the banks represent an organization of the memory array of DRAM 440. Banks 442 have individual access hardware to allow access in parallel or non-blocking access to different banks. The portion labeled 450 is a subarray of the total memory array of DRAM 440.

The memory array includes rows (ROW) and columns (COL) of memory elements. Sense amplifier (SA) 444 represents a sense amplifier to stage data for a read from the memory array or for a write to the memory array. Data can be selected into the sense amplifiers to allow detection of the value stored in a bit cell or memory cell of the array. The dashed box that includes the intersection of the labeled row and column of the memory array. The dashed portion illustrated a typical DRAM cell 448, including a transistor as a control element and a capacitor as a storage element. Bitline (BL) is the column signal line and wordline (WL) is the row signal line.

Memory controller (MEM CTLR) 418 represents a memory controller that manages access to the memory resources of DIMM 420. Memory controller 418 provides access commands to the memory devices, including sending data for a write command or receiving data for a read command. Memory controller 418 sends command and address information to the DRAM devices and exchanges data bits with the DRAM devices (either to or from, depending on the command type).

Host 410 includes OS 416, which represents a host operating system on host 410. In one example, host 410 includes error control 430 to manage error detection and memory error handling in system 400. In one example, error control 430 includes a DQ manager for DQ sparing in accordance with any description herein. In one example, some or all of error control 430 can be part of memory controller 418.

In one example, error control 430 includes ECC 432, which represents ECC at host 410. Error control 430 can be or include a memory fault tracker and detector. Remapper 434 represents the ability of error control 430 to spare a DQ, reduce the ECC applied by ECC 432, and remap the bits of the spared DQ to the freed bits of the ECC. Thus, system 400 can spare a DQ in accordance with any example herein.

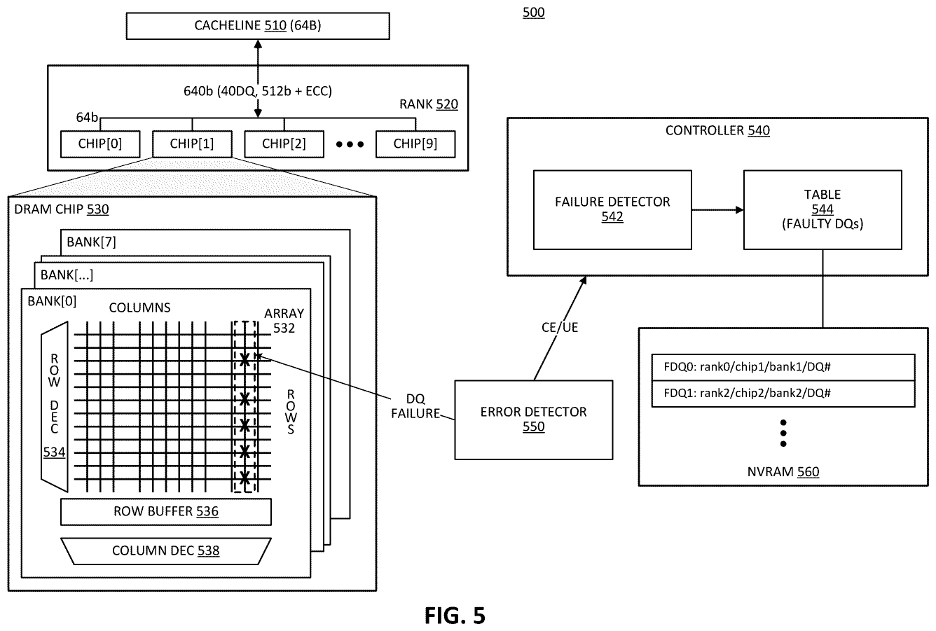

FIG. 5 is a block diagram of an example of a system in which a controller maintains a defective DQ directory. System 500 represents a system in accordance with an example of system 100 or an example of system 202. System 500 illustrates rank 520, with 10 DRAM chips, chip[0:9], that are selected with a common chip select (CS) signal. System 500 spreads cacheline 510 across the data units of rank 520. Cacheline 510 can include 640b, having 512b data plus 128b ECC over 40DQ, spreading 64b to each data unit.

DRAM chip 530 represents one of the chips of rank 520. Specifically, DRAM chip 530 shows the details of chip[1], where the other chips will have similar details. DRAM chip 530 includes 8 banks, bank[0:7]. Each bank includes array 532, with columns and rows. Row decoder (DEC) 534 selects the rows or wordlines, and column decoder (DEC) 538 selects the columns or bitlines. Row buffer 536 represents a buffer for data read from a single row. Column decoder 538 can select which portion(s) of the row to trigger for access.

The intersection of a column line with a row line represents a memory cell. The memory cells marked with ‘X’ represent bit errors at those memory cells. Error detector 550 represents hardware in system 500 to detect errors in array 532. In one example, error detector 550 detects both correctable errors and uncorrectable errors in array 532. A correctable error (CE) can refer to a row having a single error, which can be corrected by on-die ECC. An uncorrectable error (UE) can refer to a row having more than one error, which is generally not correctable by on-die ECC. Such an error can be correctable with system ECC, but the focus in system 500 is correction be on-die ECC. The arrow from error detector 550 to array 532 identifies a column failure or a DQ fault.

Error detector 550 can provide CE and UE information to controller 540, which represents control executed by a hardware component of system 500. In one example, controller 540 represents a microcontroller. In one example, controller 540 represents other hardware in the system, such as circuitry in the memory controller. Controller 540 can include failure detector 542 to identify a defective memory region associated with detected errors, and especially a DQ fault in accordance with the discussion herein. Failure detector 542 may be enabled/configured to detect failures other than DQ faults. Controller 540 can include table 544 as a defective memory region directory (DMRD) to identify faulty DQs detected by failure detector 542.

In one example, table 544 is implemented in a nonvolatile memory, as represented by nonvolatile random access memory (NVRAM) 560. NVRAM 560 enables persistence of defective region directory information between system boots. NVRAM 560 provides an example of information that can be stored in table 544. Table 544 can represent a list of defective DQs, populated with corresponding identification information. In one example, system 500 can store table 544 in static random access memory (SRAM) as an alternative to NVRAM.

FDQ0 can represent a first record for a first failed DQ (FDQ). The DQ is identified as rank0/chip1/bank1/DQ #. The second defective region, shown by record FDQ1, is identified as rank2/chip2/bank2/DQ #. Both the first and second defective DQs are identified by specific component addresses, namely, a column of a specific device in the rank, to enable the system to avoid use of the failed DQ.

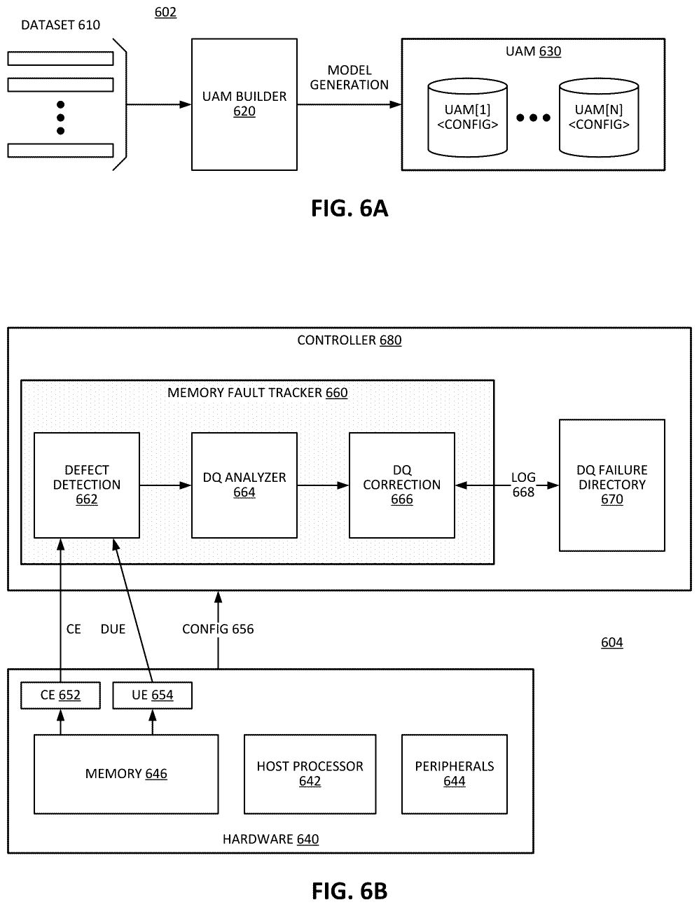

FIG. 6A is a block diagram of an example of uncorrectable error analysis training. System 602 represents elements of a training phase or a training system for prediction of memory fault or an analysis of memory fault due to uncorrectable error. In one example, system 602 can be considered an offline prediction or analysis model training, in that dataset 610 represents data for past system operations. An online system refers to a system that is currently operational. System 602 is “operational” in the sense that it is operational to generate the model, but generates the model based on historical data rather than realtime or runtime data.

In one example, system 602 includes dataset 610. Dataset 610 can represent a large-scale CE and UE failure dataset that includes microlevel memory error information. The microlevel memory error information can include indications of failure based on bit, DQ, row, column, device, rank, channel, DIMM, or other configuration, or a combination of information. In one example, dataset 610 includes a timestamp to indicate when errors occurred. In one example, dataset 610 includes hardware configuration information associated with the error dataset. The hardware configuration information can include information such as memory device information, DIMM manufacturer part number, CPU model number, system board details, or other information, or a combination of such information. In one example, dataset 610 can represent information collected from large-scale datacenter implementations.

System 602 includes UE analysis model (UAM) builder 620 to process data from dataset 610 to generate a model that indicates configurations with error patterns that are likely to result in a UE. In one example, UAM builder 620 represents software logic for AI (artificial intelligence) training to generate the model. In this context, AI represents neural network training or other form of data mining to identify patterns of relationship from large data sets. In one example, UAM builder 620 generates UAM 630 for each hardware configuration, based on microlevel (e.g., bit, DQ, row, column, device, rank) CE patterns or indicators. Thus, UAM 630 can include N different UAMs (UAM[1:N]) based on different configuration information (CONFIG).

In one example, UAM 630 includes a separate analysis model for each combination of a CPU model and a DIMM manufacturer or part number. Such granularity for different combinations of CPU model and DIMM part number can identify fault hardware patterns differently, seeing that the different hardware configurations can cause different hardware fault statuses. For example, DIMMs from the same manufacturer or with the same part number but with a different CPU model may implement ECC differently in the memory controller, causing the same faulty hardware status of a DIMM to exhibit different observations due to a different behavior of ECC implementation. A CPU family may provide multiple ECC patterns, allowing a customer to choose the ECC based on the application the customer selects. Similarly, for the same CPU model with a DIMM from a different manufacturer or with a different part number, the faulty status of a DIMM may exhibit different observations due to the different design and implementation of the DIMM hardware. Thus, in one example, system 602 creates analysis models per combination of CPU model and DIMM manufacture or part number to provide improved analysis accuracy performance.

FIG. 6B is a block diagram of an example of sparing based on uncorrectable error analysis. System 604 represents an example of a system with UE fault analysis to detect DQ fault information for sparing in accordance with system 300. In one example, system 604 implements an example of UAM 630 of system 602 in defect detection 662. Whereas system 602 can operate based on historical or stored information, system 604 can be considered a runtime memory failure analysis system in that system 604 operates on runtime or realtime parameters as they occur as well as on historical information.

In one example, system 602 of FIG. 6A provides a machine-learning based uncorrectable memory error analysis mechanism at the level of the memory device. In one example, system 604 utilizes system 602 to generate a runtime prediction or determination of faulty components to determine what component is the likely cause of a detected UE or other error. For example, system 604 can generate a prediction or a determination of a cause of an error and trigger a correction action specific to the cause of the error.

System 604 includes controller 680, which can be a dedicated microcontroller or other hardware, or can represent firmware to execute on a shared controller or hardware shared with other control or management functions in the computer system. In one example, controller 680 is a controller of a host hardware platform, such as hardware 640. The host hardware platform can include a CPU or other host processor 642. Memory 646 can represent multiple memory device or multiple parallel memory resources. In one example, controller 680 represents a controller disposed on a substrate of a computer system. In one example, the substrate is a motherboard. In one example, the substrate is a memory module board. In one example, the substrate is a logic die of an HBM stack (e.g., a control layer on which the memory dies are disposed).

Controller 680 executes memory fault tracker (MFT) 660, which represents an engine to determine a component that caused an error and trigger runtime sparing action for a memory region associated with the faulty component, in accordance with any example described. Hardware 640 represents the hardware of the system to be monitored for memory errors. Hardware 640 provides hardware configuration (CONFIG) 656 to MFT 660 for error analysis. Configuration 656 represents the specific hardware components and their features and settings. Hardware 640 can include host processor 642, which represents processing resources for a computer system, peripherals 644, and memory 646.

Peripherals 644 represent components and features of hardware 640 that can change the handling of memory errors. Thus, hardware components and software/firmware configuration of the hardware components that can affect how memory errors are handled can be included for consideration in configuration information to send to MFT 660 for memory fault analysis. Examples of peripheral configuration can include peripheral control hub (PCH) configuration, management engine (ME) configuration, quick path interconnect (QPI) capability, or other components or capabilities.

Memory 646 represents the memory resources for which errors can be identified. In one example, system 604 monitors memory 646 to determine when correctable errors and uncorrectable errors occur in the memory. For example, such errors can be detected in a scrubbing operation or as part of an error handling routine. CE 652 represents CE data for correctable errors detected in data of memory 646. UE 654 represents UE data for detected, uncorrectable errors (DUES) detected in data of memory 646.

In one example, defect detection 662 represents a UE analyzer that implements information from UAM 630 to identify a faulty component in memory 646 based on the historical error information correlated with system architecture information. With the identification of an error at the hardware component level, memory fault tracker 660 can specifically identify what memory region(s) are defective based on the faulty component.

DQ analyzer 664 specifically represents a component to enable memory fault tracker 660 to identify faulty DQs in memory 646 based on detection and prediction by defect detection 662. In one example, system 604 stores faulty DQ information in DQ failure directory 670 as log 668. DQ failure directory 670 can be stored in a nonvolatile RAM (NVRAM), flash memory, or other persistent memory, which enables system 604 to store sparing information persistently between boots. Certain memory faults will persist across power cycles of system 604.

DQ correction 666 enables MFT 660 to determine a corrective action to implement to address the faulty DQ. As described herein, the corrective action can include DQ sparing, by remapping data bits from a faulty DQ to ECC bits freed up by reducing ECC. In one example, the system reduces the ECC level and then remaps bits. If the ECC level has already been reduced, and there are free ECC bits available, the system can remap the bits from the faulty DQ without needing to change the ECC level.

A system in accordance with system 604 can respond to detection of an error in memory based on fault-aware analysis. The fault-aware analysis enables the system to determine, such as through a statistical prediction, a specific hardware element of the memory that caused the error, identifying a faulty component and a faulty memory region associated with the faulty component. In statistical analysis, a “prediction” can refer to a conclusion reached by computational analysis. In a computational sense, a computed prediction can identify a prior event or prior cause. The prediction as described herein can refer to a future prediction of a component that is likely to cause an uncorrectable error (UE) or a determination of a cause at the component level of a component that generated a UE. Thus, the system can prevent the occurrence of a UE, or can provide a correction action in response to detection of a UE.

A system in accordance with system 604, with fault analysis or fault-aware analysis, can account for the circuit-level architecture of the memory rather than the mere number or frequency of correctable errors (CEs). Observation of error patterns related to circuit structure can enable the system to predict with confidence the component that is the source of the error. A fault prediction for a detected UE or predicted UE can refer to the result of a computational analysis that identifies a most likely cause of an error that occurred prior in time (i.e., for a detected UE) or for a UE that is expected to occur (i.e., predicted UE).

In response to an error, the system can correlate a hardware configuration of the memory device with historical data indicating memory faults for hardware elements of the hardware configuration. Thus, the system can account for rank, bank, row, column, or other information related to the physical organization and structure of the memory in predicting uncorrectable errors. Based on a determination of the specific component that caused a detected error (whether a CE or a UE), the system can identify a region of memory associated with the detected error and mirror the faulty region to a reserved memory space of the memory device for access to the data that was stored in the faulty region.

A runtime micro-level-fault-aware policy based on tracking error history can detect defective memory regions (e.g., worldline, bitline/DQ (data pin), subrange of wordline/bitline, row, column, device, rank) to infer whether a certain microlevel memory component (e.g., column, row) is faulty. The analysis of faulty components can occur with hardware on the system platform.

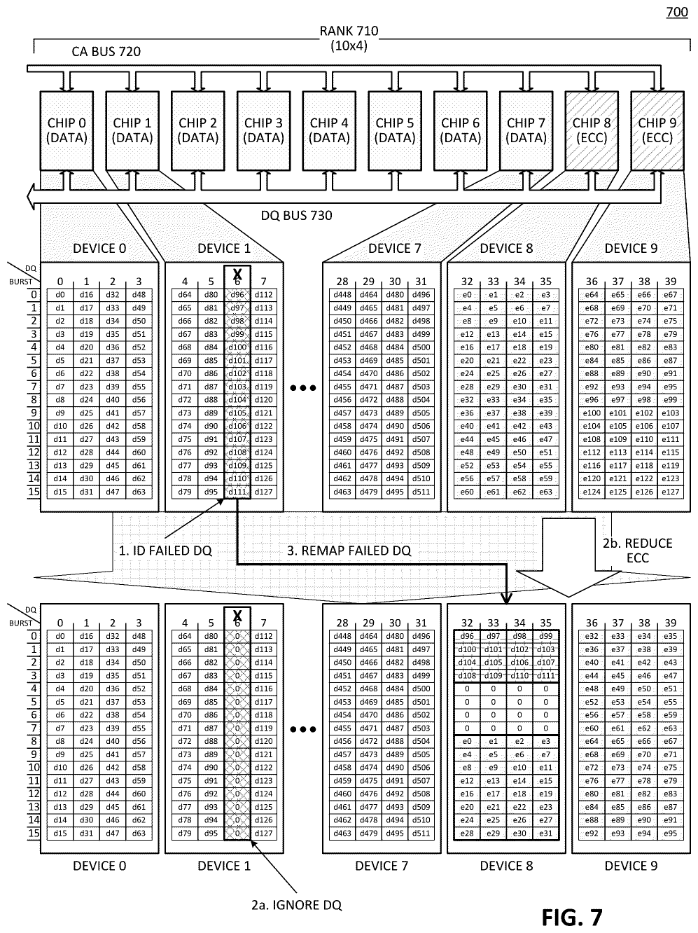

FIG. 7 is a block diagram of an example of a system that reduces ECC and remaps for a failed DQ. System 700 illustrates a specific example of a 10×4 rank having 8 data devices (chip[0:7]) and 2 ECC devices (chip[8:9]). Rank 710 can be an example of a DDR5 DIMM. CA bus 720 represents a command/address bus for rank 710. DQ bus 730 represents the data bus for rank 710.

System 700 illustrates details of the data for a read transaction. The data for a write transaction would be similar to what is shown, but could be presented in reverse order. The data is illustrated as data bits per DQ of data bus 730 per unit interval (UI) of the burst length (UI[0:15]). It will be understood that a system with 8×4 data devices with BL16 generates 8*4*16=512 bits of data. The specific data is labeled d0, d1, d2, . . . , d511, d512 for the 32 DQs, DQ[0:31].

It will be understood that the data bit identification illustrated in system 700 is not necessarily how the data will be interpreted by the memory controller. Rather the data bit identification illustrated is simply for purposes of simplicity in description. It will be noted that while d0, d1, d2, . . . , is illustrated in column major format for the data devices (DQ0 has d[0:15], DQ1 has d[16:31], DQ2 has d[32:47], and so forth), the ECC bits are illustrated in row major format per ECC device. With the row major format per ECC device, e[0:3] is spread across DQ32, DQ33, DQ34, and DQ35, respectively, in a first row, e[4:7] in a second row, e[8:11] in a third row, and so forth. For device 9 having DQ36, DQ37, DQ38, and DQ49, the first row illustrates e[64:67], the second row illustrates e[68:71], and so forth.

Consider a DQ fault detected on DQ6, illustrated by the ‘X’ and the box around the data bits of DQ6. Thus, data bits d[96:111] cannot be properly exchanged between the DRAM devices and the memory controller. In response to detection of the failed DQ, system 700 can remap the bits of DQ6 to ECC bits.

As illustrated, first the system identifies (IDs) the failed DQ (1). Next, the system can ignore the failed DQ (2a) and reduce the ECC (2b). The first diagram of the memory devices illustrates 128 bits of ECC. The reduction illustrates that bits of Device 8 are allocated for user data, and the number of ECC bits in Device 8 are reduced by half. Thus, system 700 ends up with 96 bits of ECC. As illustrated, the system can remap (3) the failed DQ to the freed ECC bits.

System 700 illustrates an example where the data bits of failed DQ6 are remapped to multiple DQs of ECC Device 8, with d96, d97, d98, and d99 on a first row of DQ32, DQ33, DQ34, and DQ35, respectively, and d[100:111] similarly spread across DQ[32:35]. It can be observed that reducing to 96 bits of ECC frees up more data bits than needed for DQ6, and thus, those bits can remain unused across DQ[32:35] for UI[4:7]. ECC bits e[0:31] are spread across DQ[32:35] on UI[8:15]. Thus, system 700 can downgrade the ECC mode from 128-bit ECC to 96-bit ECC, and then remap the DQ6 bits into freed ECC bits in Device 8. When a cacheline is read from a bank affected by the failure of DQ6 can be remapped, with data redirected from the ECC bits back to DQ6.

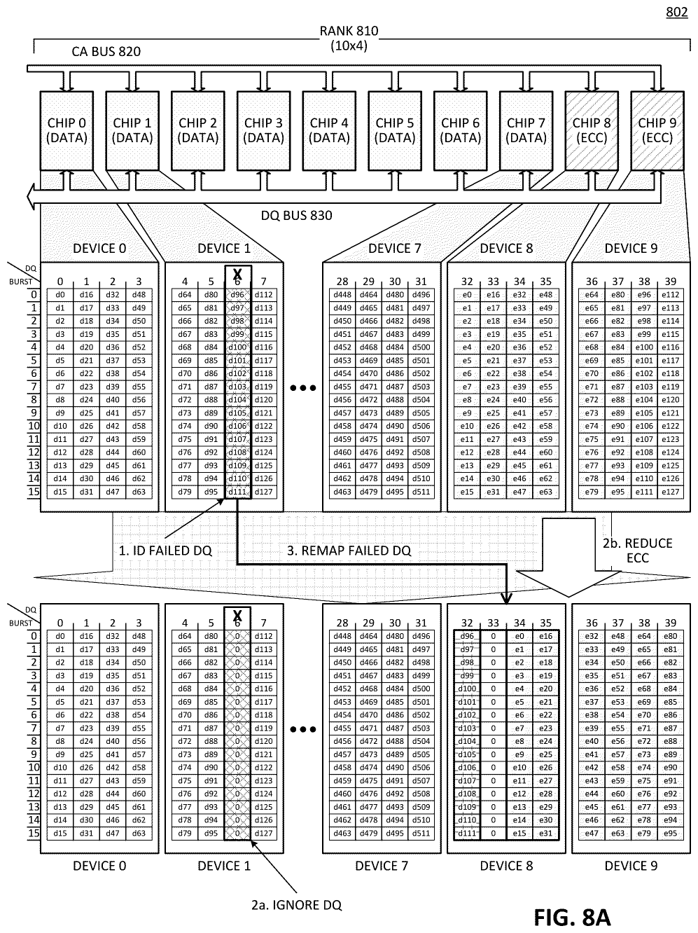

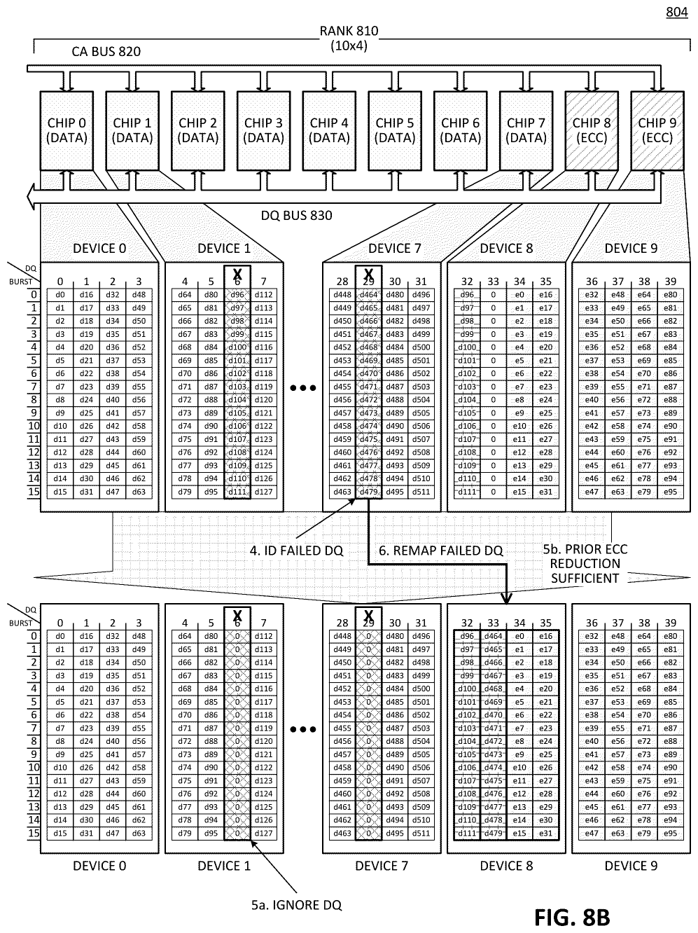

FIG. 8A is a block diagram of an example of a system that reduces ECC and remaps for a failed DQ. System 802 illustrates a specific example of a 10×4 rank having 8 data devices (chip[0:7]) and 2 ECC devices (chip[8:9]). Rank 810 can be an example of a DDR5 DIMM. CA bus 820 represents a command/address bus for rank 810. DQ bus 830 represents the data bus for rank 810.

System 802 illustrates details of the data for a read transaction. The data for a write transaction would be similar to what is shown, but could be presented in reverse order. The data is illustrated as data bits per DQ of data bus 830 per unit interval (UI) of the burst length, UI[0:15]. It will be understood that a system with 8×4 data devices with BL16 generates 8*4*16=512 bits of data. The specific data is labeled d0, d1, d2, d511, d512 for the 32 DQs, DQ[0:31].

It will be understood that the data bit identification illustrated in system 802 is not necessarily how the data will be interpreted by the memory controller. Rather the data bit identification illustrated is simply for purposes of simplicity in description. It will be noted that d0, d1, d2, . . . , is illustrated in column major format for the data devices (DQ0 has d[0:15], DQ1 has d[16:31], DQ2 has d[32:47], and so forth), and the ECC bits are also illustrated in column major format. Thus, DQ32 of Device 8 has e[0:15], DQ33 has e[16:31], and so forth.

Consider a DQ fault detected on DQ6, illustrated by the ‘X’ and the box around the data bits of DQ6. Thus, data bits d[96:111] cannot be properly exchanged between the DRAM devices and the memory controller. In response to detection of the failed DQ, system 802 can remap the bits of DQ6 to ECC bits.

As illustrated, first the system identifies (IDs) the failed DQ (1). Next, the system can ignore the failed DQ (2a) and reduce the ECC (2b). The first diagram of the memory devices illustrates 128 bits of ECC. The reduction illustrates that bits of Device 8 are allocated for user data, and the number of ECC bits in Device 8 are reduced by half. Thus, system 802 ends up with 96 bits of ECC. As illustrated, the system can remap (3) the failed DQ to the freed ECC bits.

System 802 illustrates an example where the data bits of failed DQ6 are remapped to a single DQ of ECC Device 8, with d[96:111] remapped to DQ32. It can be observed that reducing to 96 bits of ECC frees up more data bits than needed for DQ6, and thus, those bits can remain unused in DQ33. ECC bits e[0:15] are then in DQ34, and e[16:31] are in DQ35. Thus, system 802 can downgrade the ECC mode from 128-bit ECC to 96-bit ECC, and then remap the DQ6 bits into freed ECC bits in Device 8. When a cacheline is read from a bank affected by the failure of DQ6 can be remapped, with data redirected from the ECC bits back to DQ6.

FIG. 8B is a block diagram of an example of a system that reduces ECC and remaps for two failed DQs. System 804 illustrates an example of system 802 after detection of a second DQ failure. Thus, after one DQ sparing in system 802, the system changes from 128-bit ECC to 96-bit ECC, remapping the failed DQ to data bits of an ECC device.

Now consider a DQ fault detected on DQ29, illustrated by the ‘X’ and the box around the data bits of DQ29. Thus, data bits d[464:479] cannot be properly exchanged between the DRAM devices and the memory controller. In response to detection of the failed DQ system 804 can remap the bits of DQ29 to ECC bits that were already freed from the previous ECC reduction.

As illustrated, first the system identifies (IDs) the failed DQ (4). Next, the system can ignore the failed DQ (5a), but does not need to reduce the ECC, because the prior ECC reduction is sufficient to spare the bits of DQ29 (5b). The first diagram of the memory devices illustrates 96 bits of ECC. The second diagram illustrates the same number of ECC bits, but whereas there are 16 unused bits for DQ33 in the first diagram, in the second diagram, the 16 bits of DQ33 are used for the second failed DQ. Thus, system 804 remaps d[464:479] to DQ33.

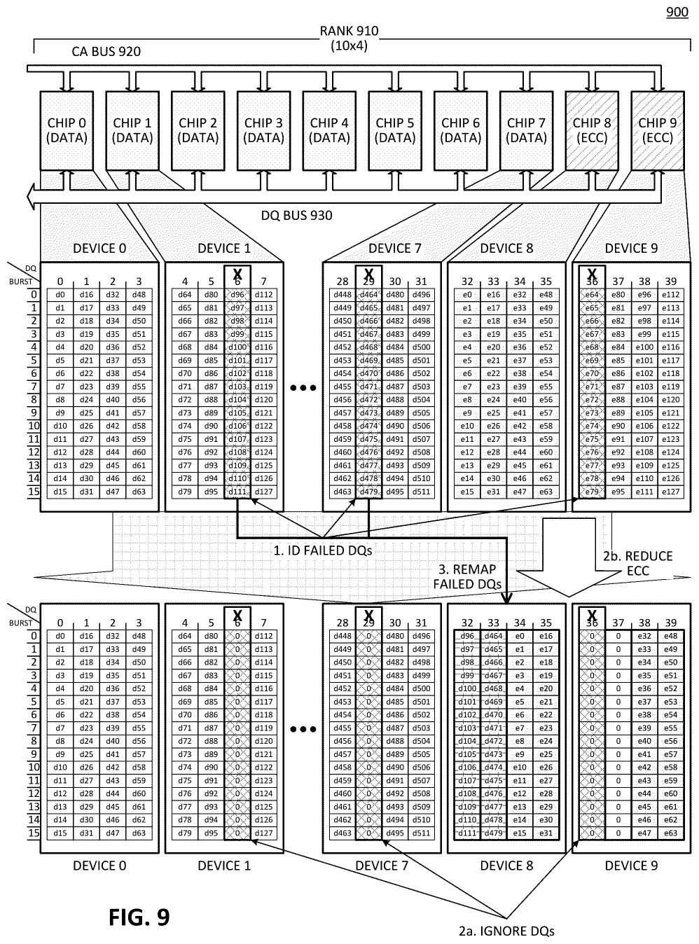

FIG. 9 is a block diagram of an example of a system that reduces ECC and remaps for three failed DQs. System 900 illustrates a specific example of a 10×4 rank having 8 data devices (chip[0:7]) and 2 ECC devices (chip[8:9]). Rank 910 can be an example of a DDR5 DIMM. CA bus 920 represents a command/address bus for rank 910. DQ bus 930 represents the data bus for rank 910.

System 900 illustrates details of the data for a read transaction. The data for a write transaction would be similar to what is shown, but could be presented in reverse order. The data is illustrated as data bits per DQ of data bus 930 per unit interval (UI) of the burst length, UI[0:15]. It will be understood that a system with 8×4 data devices with BL16 generates 8*4*16=512 bits of data. The specific data is labeled d0, d1, d2, d511, d512 for the 32 DQs, DQ[0:31].

It will be understood that the data bit identification illustrated in system 900 is not necessarily how the data will be interpreted by the memory controller. Rather the data bit identification illustrated is simply for purposes of simplicity in description. It will be noted that d0, d1, d2, . . . , is illustrated in column major format for the data devices (DQ0 has d[0:15], DQ1 has d[16:31], DQ2 has d[32:47], and so forth), and the ECC bits are also illustrated in column major format. Thus, DQ32 of Device 8 has e[0:15], DQ33 has e[16:31], and so forth.

Consider multiple DQ faults detected, on DQ6, DQ29, and DQ36, illustrated by the ‘X’ and the boxes around the data bits of each DQ. The three different DQ faults could be detected at once, or could be detected one DQ fault at a time, remapping different DQs as the faults are detected. As illustrated, data bits d[96:111], d[464:479], and e[64:79] cannot be properly exchanged between the DRAM devices and the memory controller. In response to detection of the failed DQs, system 900 can remap the bits of data DQs and can remove from use the bits of the failed ECC DQ.

As illustrated, first the system identifies (IDs) the failed DQs (1). Next, the system can ignore the failed DQs (2a) and reduce the ECC (2b). The first diagram of the memory devices illustrates 128 bits of ECC, where 16 of the ECC bits are unavailable with failed DQ36. The ECC reduction illustrates that bits of Device 8 are allocated for user data, the number of ECC bits in Device 8 is reduced by half, and the number of ECC bits in Device 9 is also reduced by half. Thus, system 900 ends up with 64 bits of ECC.

When three failed DQs (chip1/bank X/DQ6; chip7/bank X/DQ29; chip9/bank X/DQ35) are identified in a bank, a microcontroller or firmware logic spares the failed DQ6, DQ29 and DQ35 with switching the 10×4 device from 10×4 128-bit ECC mode to 9×4 64-bit ECC mode for all the cache line data access to/from the impacted bank X. With degrading ECC mode from 10×4 128-bit to 9×4 64-bit, up to 64 ECC bits are released and can be repurposed to store the data from spared DQ. In one example, when the bank gets accessed, it is redirected from spared DQs to the released ECC bits on-the-fly for data write and remapped with redirected data from ECC bits back to original DQ locations for reads.

As illustrated, the system can remap (3) the failed data DQs to the freed ECC bits. System 900 illustrates an example where the data bits of failed DQ6 and DQ29 are remapped to DQ32 and DQ33, respectively, of ECC Device 8, with d[96:111] remapped to DQ32 and d[464:479] remapped to DQ33. The ECC bits of DQ36 are ignored, and the bits of DQ37 are freed up. Thus, the 64 ECC bits can be stored in DQ34, DQ35, DQ38, and DQ39. As illustrated, system 900 can downgrade the ECC mode from 128-bit ECC mode to 64-bit ECC mode, including removing ECC bits from use, and remapping the bits of the failed data DQs into freed ECC bits.

It will be understood that system 900 could potentially support another DQ failure. If another data DQ fails, it could be remapped to DQ37, which has the freed up ECC bits. If another ECC DQ fails, the ECC bits can be remapped. While system 900 illustrates DQ6 mapped to DQ32, and DQ29 mapped to DQ33, it will be understood that there is no requirement for maintaining any type of DQ sequence or order when remapping the bits. For example, DQ29 could be remapped to DQ32 and DQ6 remapped to DQ33. Additionally, while the ECC bits are illustrated as always in order, remapping could also remap the order of ECC bits.

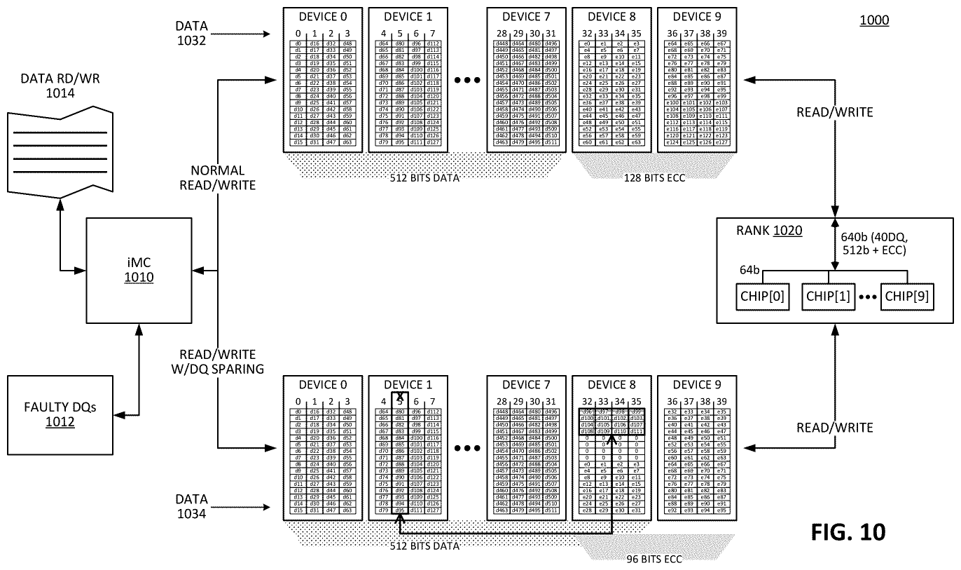

FIG. 10 is a block diagram of an example of a data read/write flow with DQ sparing. System 1000 includes integrated memory controller (iMC) 1010 or other memory controller that can generate reads and writes of cachelines of data (e.g., 512 bits) of rank 1020, which represents the memory resources. Data RD/WR 1014 represents the read or write transaction of the cacheline of data.

System 1000 illustrates data 1032, which represents the data for a normal read/write transaction where there are no DQ failures, and data 1034, which represents the data for a read/write transaction with DQ sparing. When iMC 1010 generates a read or write, in one example, it checks if the bank accessed has a faulty DQ identified and spared. Faulty DQs 1012 represents a table or directory that identifies spared DQs.

Rank 1020 includes Chip[0:9], which are data chips or data devices. The rank provides 640 bits of data per memory access transaction, with 512 bits of data and 128 bits of ECC from 40 DQs. Data 1032 illustrates data d[0:63] in Device 0, data d[64:127] in Device 1, . . . , data d[464:511] in Device 7, ECC bits e[0:64] in Device 8, for a total of 512 data bits, and e[65:127] in Device 9, for a total of 128 ECC bits.

For the normal read/write, with no faulty DQs identified and spared, system 1000 can perform a normal read/write with the configured ECC mode. As illustrated, the configured ECC mode is 128-bit single device data correction (SDDC) mode.

In one example, system 1000 determines that DQ5 is faulty, reduces the ECC mode, and remaps the bits of DQ5 to freed ECC bits of Device 8. With the faulty DQ, system 1000 can implement DQ sparing. As illustrated, the 512 bits of data come from Device[0:8] instead of just from Device[0:7] as with a normal read/write. Then, Device[8:9] provide 96 bits of ECC instead of 128 bits.

In one example, with a data write, if the write is to a bank with a faulty DQ identified, iMC 1010 can perform DQ sparing on-the-fly with switching the ECC mode to 96-bit ECC and redirecting the data from retired DQ5 to freed and repurposed ECC bits of Device 8. iMC 1010 can write the remapped data to the memory device and store the DQ sparing record.

In one example, with a data read, when the read is from a bank with a DQ spared, iMC 1010 can switch to 96-bit ECC mode and redirect the data stored in the repurposed ECC bits to the original location of the spared DQ and return the remapped data back to the requesting application/process.

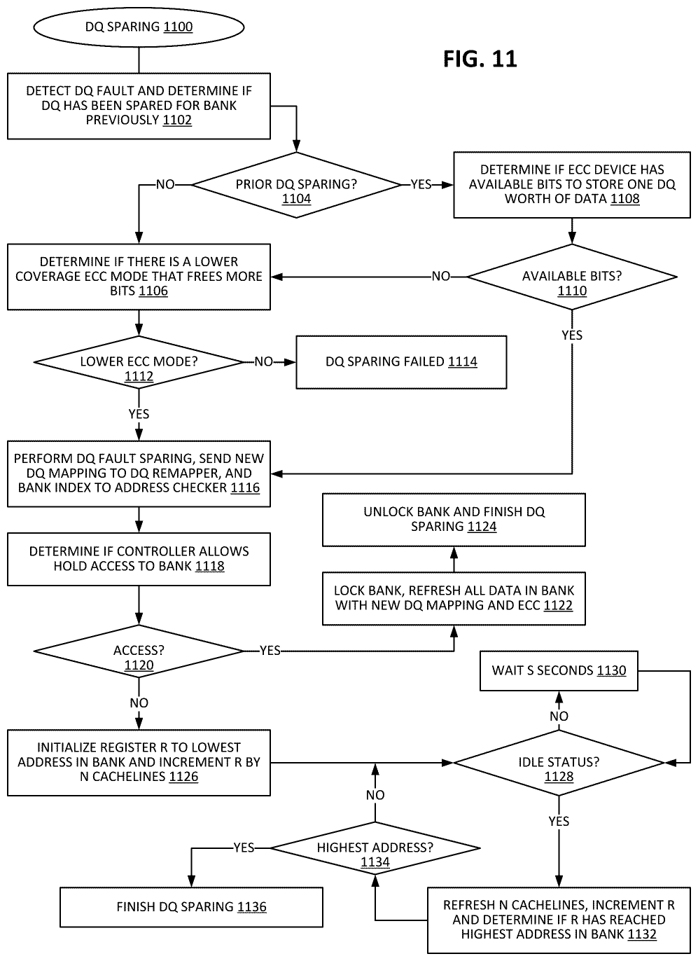

FIG. 11 is a flow diagram of an example of a process for DQ sparing. Process 1100 represents a process for DQ sparing that can be executed by any system described herein. In one example, the system can detect a DQ fault and determine if the DQ has been spared for the bank previously, at 1102. As described herein, in one example, the detection of a DQ fault can be performed by an error detector. If there has not been prior DQ sparing, at 1104 NO branch, in one example, the DQ manager can determine if there is a lower coverage ECC mode that frees more bits, at 1106. A lower coverage ECC mode can free more bits to spare the faulty DQ.

If there has been prior DQ sparing, at 1104 YES branch, in one example, the DQ manager can determine if an ECC device has available bits to store one DQ worth of data, at 1108. For example, if a DQ has been previously spared and two DQ's worth of data were freed up from the ECC device or ECC devices, there could be bits available to spare another DQ.

If the system does not have a lower ECC mode available, at 1112 NO branch, in one example, the DQ sparing fails, at 1114. If there is a lower ECC mode that can free up bits, at 1112 YES branch, the system can perform DQ fault sparing, sending a new DQ mapping to the DQ remapper, and the bank index to the address checker, at 1116. Additionally, if there are available bits to spare another DQ, at 1110 YES branch, the system can perform DQ fault sparing.

The system can determine if the controller (e.g., a memory controller or iMC) allows hold access to the bank, at 1118. If the controller allows hold access to the bank, at 1120 YES branch, the system can lock the bank, refreshing all data in the bank with the new DQ mapping, and setting the new ECC mode, at 1122. After the refreshing, the system can unlock the bank, and the DQ sparing finishes, at 1124.

If controller hold access to the bank is not allowed, at 1120 NO branch, in one example, the system initializes register R to the lowest address in the bank and increments R by N cachelines, at 1126. If the bank is not in an idle state, at 1128 NO branch, the system can wait S seconds, at 1130, and check again to see if the bank is idle. If the bank is in an idle state, at 1128 YES branch, the system can refresh N cachelines, increment R, and determine if R has reached the highest address in the bank, at 1132.

If register R reaches the highest address in the bank, at 1134 YES branch, the DQ sparing finishes, at 1136. If R has not reached the highest address in the bank, at 1134 NO branch, the flow can return to determining if the bank is in an idle state to continue refreshing, at 1128.

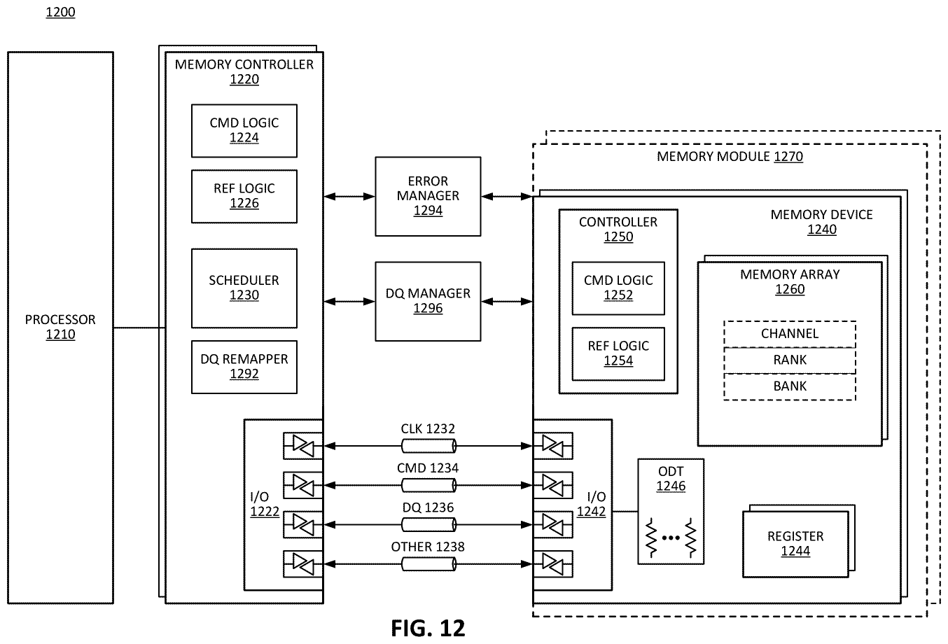

FIG. 12 is a block diagram of an example of a memory subsystem in which DQ sparing can be implemented. System 1200 includes a processor and elements of a memory subsystem in a computing device. System 1200 is an example of a system in accordance with an example of system 100, an example of system 202, system 300, system 400, or system 1000.

In one example, system 1200 includes error manager 1294 or other memory fault tracking engine to determine a component that is a cause of a detected UE. In one example, error manager 1294 is part of memory controller 1220. In one example, error manager 1294 is part of a controller circuit other than the memory controller. In one example, system 1200 includes DQ manager 1296, which represents a controller that manages DQ sparing when a faulty DQ is detected. The DQ sparing can be performed in accordance with any example described. In one example, memory controller 1220 includes DQ remapper 1292 to work in conjunction with DQ manager 1296 to implement DQ sparing. The DQ sparing includes repurposing freed ECC bits for the data of the spared DQ. DQ remapper 1292 can remap the data to return to the program that triggered a read, or remap the data from a program that triggered a write.

Processor 1210 represents a processing unit of a computing platform that may execute an operating system (OS) and applications, which can collectively be referred to as the host or the user of the memory. The OS and applications execute operations that result in memory accesses. Processor 1210 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 1200 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 (HBM version 2, JESD235C, originally published by JEDEC in January 2020), HBM3 (HBM version 3, JESD238, originally published by JEDEC in January 2022), or others or combinations of memory technologies, and technologies based on derivatives or extensions of such specifications.

Memory controller 1220 represents one or more memory controller circuits or devices for system 1200. Memory controller 1220 represents control logic that generates memory access commands in response to the execution of operations by processor 1210. Memory controller 1220 accesses one or more memory devices 1240. Memory devices 1240 can be DRAM devices in accordance with any referred to above. In one example, memory devices 1240 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 1220 manages a separate memory channel, although system 1200 can be configured to have multiple channels managed by a single controller, or to have multiple controllers on a single channel. In one example, memory controller 1220 is part of host processor 1210, such as logic implemented on the same die or implemented in the same package space as the processor.

Memory controller 1220 includes I/O interface logic 1222 to couple to a memory bus, such as a memory channel as referred to above. I/O interface logic 1222 (as well as I/O interface logic 1242 of memory device 1240) can include pins, pads, connectors, signal lines, traces, or wires, or other hardware to connect the devices, or a combination of these. I/O interface logic 1222 can include a hardware interface. As illustrated, I/O interface logic 1222 includes at least drivers/transceivers for signal lines. Commonly, wires within an integrated circuit interface couple with a pad, pin, or connector to interface signal lines or traces or other wires between devices. I/O interface logic 1222 can include drivers, receivers, transceivers, or termination, or other circuitry or combinations of circuitry to exchange signals on the signal lines between the devices. The exchange of signals includes at least one of transmit or receive. While shown as coupling I/O 1222 from memory controller 1220 to I/O 1242 of memory device 1240, it will be understood that in an implementation of system 1200 where groups of memory devices 1240 are accessed in parallel, multiple memory devices can include I/O interfaces to the same interface of memory controller 1220. In an implementation of system 1200 including one or more memory modules 1270, I/O 1242 can include interface hardware of the memory module in addition to interface hardware on the memory device itself. Other memory controllers 1220 will include separate interfaces to other memory devices 1240.

The bus between memory controller 1220 and memory devices 1240 can be implemented as multiple signal lines coupling memory controller 1220 to memory devices 1240. The bus may typically include at least clock (CLK) 1232, command/address (CMD) 1234, and write data (DQ) and read data (DQ) 1236, and zero or more other signal lines 1238. In one example, a bus or connection between memory controller 1220 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 1200 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 1220 and memory devices 1240. An example of a serial bus technology is 8B10B encoding and transmission of high-speed data with embedded clock over a single differential pair of signals in each direction. In one example, CMD 1234 represents signal lines shared in parallel with multiple memory devices. In one example, multiple memory devices share encoding command signal lines of CMD 1234, and each has a separate chip select (CS_n) signal line to select individual memory devices.

It will be understood that in the example of system 1200, the bus between memory controller 1220 and memory devices 1240 includes a subsidiary command bus CMD 1234 and a subsidiary bus to carry the write and read data, DQ 1236. In one example, the data bus can include bidirectional lines for read data and for write/command data. In another example, the subsidiary bus DQ 1236 can include unidirectional write signal lines for write and data from the host to memory, and can include unidirectional lines for read data from the memory to the host. In accordance with the chosen memory technology and system design, other signals 1238 may accompany a bus or sub bus, such as strobe lines DQS. Based on design of system 1200, or implementation if a design supports multiple implementations, the data bus can have more or less bandwidth per memory device 1240. For example, the data bus can support memory devices that have either a ×4 interface, a ×8 interface, a ×16 interface, or other interface. The convention “xW,” where W is an integer that refers to an interface size or width of the interface of memory device 1240, which represents a number of signal lines to exchange data with memory controller 1220. The interface size of the memory devices is a controlling factor on how many memory devices can be used concurrently per channel in system 1200 or coupled in parallel to the same signal lines. In one example, high bandwidth memory devices, wide interface devices, or stacked memory configurations, or combinations, can enable wider interfaces, such as a ×128 interface, a ×256 interface, a ×512 interface, a ×1024 interface, or other data bus interface width.

In one example, memory devices 1240 and memory controller 1220 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 1240 can transfer data on each UI. Thus, a ×8 memory device operating on BL8 can transfer 64 bits of data (8 data signal lines times 8 data bits transferred per line over the burst). It will be understood that this simple example is merely an illustration and is not limiting.

Memory devices 1240 represent memory resources for system 1200. In one example, each memory device 1240 is a separate memory die. In one example, each memory device 1240 can interface with multiple (e.g., 2) channels per device or die. Each memory device 1240 includes I/O interface logic 1242, which has a bandwidth determined by the implementation of the device (e.g., ×16 or ×8 or some other interface bandwidth). I/O interface logic 1242 enables the memory devices to interface with memory controller 1220. I/O interface logic 1242 can include a hardware interface, and can be in accordance with I/O 1222 of memory controller, but at the memory device end. In one example, multiple memory devices 1240 are connected in parallel to the same command and data buses. In another example, multiple memory devices 1240 are connected in parallel to the same command bus, and are connected to different data buses. For example, system 1200 can be configured with multiple memory devices 1240 coupled in parallel, with each memory device responding to a command, and accessing memory resources 1260 internal to each. For a Write operation, an individual memory device 1240 can write a portion of the overall data word, and for a Read operation, an individual memory device 1240 can fetch a portion of the overall data word. The remaining bits of the word will be provided or received by other memory devices in parallel.

In one example, memory devices 1240 are disposed directly on a motherboard or host system platform (e.g., a PCB (printed circuit board) or substrate on which processor 1210 is disposed) of a computing device. In one example, memory devices 1240 can be organized into memory modules 1270. In one example, memory modules 1270 represent dual inline memory modules (DIMMs). In one example, memory modules 1270 represent other organization of multiple memory devices to share at least a portion of access or control circuitry, which can be a separate circuit, a separate device, or a separate board from the host system platform. Memory modules 1270 can include multiple memory devices 1240, and the memory modules can include support for multiple separate channels to the included memory devices disposed on them. In another example, memory devices 1240 may be incorporated into the same package as memory controller 1220, such as by techniques such as multi-chip-module (MCM), package-on-package, through-silicon via (TSV), or other techniques or combinations. Similarly, in one example, multiple memory devices 1240 may be incorporated into memory modules 1270, which themselves may be incorporated into the same package as memory controller 1220. It will be appreciated that for these and other implementations, memory controller 1220 may be part of host processor 1210.

Memory devices 1240 each include one or more memory arrays 1260. Memory array 1260 represents addressable memory locations or storage locations for data. Typically, memory array 1260 is managed as rows of data, accessed via wordline (rows) and bitline (individual bits within a row) control. Memory array 1260 can be organized as separate channels, ranks, and banks of memory. Channels may refer to independent control paths to storage locations within memory devices 1240. Ranks may refer to common locations across multiple memory devices (e.g., same row addresses within different devices) in parallel. Banks may refer to sub-arrays of memory locations within a memory device 1240. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 1240 include one or more registers 1244. Register 1244 represents one or more storage devices or storage locations that provide configuration or settings for the operation of the memory device. In one example, register 1244 can provide a storage location for memory device 1240 to store data for access by memory controller 1220 as part of a control or management operation. In one example, register 1244 includes one or more Mode Registers. In one example, register 1244 includes one or more multipurpose registers. The configuration of locations within register 1244 can configure memory device 1240 to operate in different “modes,” where command information can trigger different operations within memory device 1240 based on the mode. Additionally or in the alternative, different modes can also trigger different operation from address information or other signal lines depending on the mode. Settings of register 1244 can indicate configuration for I/O settings (e.g., timing, termination or ODT (on-die termination) 1246, driver configuration, or other I/O settings).

In one example, memory device 1240 includes ODT 1246 as part of the interface hardware associated with I/O 1242. ODT 1246 can be configured as mentioned above, and provide settings for impedance to be applied to the interface to specified signal lines. In one example, ODT 1246 is applied to DQ signal lines. In one example, ODT 1246 is applied to command signal lines. In one example, ODT 1246 is applied to address signal lines. In one example, ODT 1246 can be applied to any combination of the preceding. The ODT settings can be changed based on whether a memory device is a selected target of an access operation or a non-target device. ODT 1246 settings can affect the timing and reflections of signaling on the terminated lines. Careful control over ODT 1246 can enable higher-speed operation with improved matching of applied impedance and loading. ODT 1246 can be applied to specific signal lines of I/O interface 1242, 1222 (for example, ODT for DQ lines or ODT for CA lines), and is not necessarily applied to all signal lines.

Memory device 1240 includes controller 1250, which represents control logic within the memory device to control internal operations within the memory device. For example, controller 1250 decodes commands sent by memory controller 1220 and generates internal operations to execute or satisfy the commands. Controller 1250 can be referred to as an internal controller, and is separate from memory controller 1220 of the host. Controller 1250 can determine what mode is selected based on register 1244, and configure the internal execution of operations for access to memory resources 1260 or other operations based on the selected mode. Controller 1250 generates control signals to control the routing of bits within memory device 1240 to provide a proper interface for the selected mode and direct a command to the proper memory locations or addresses. Controller 1250 includes command logic 1252, which can decode command encoding received on command and address signal lines. Thus, command logic 1252 can be or include a command decoder. With command logic 1252, memory device can identify commands and generate internal operations to execute requested commands.

Referring again to memory controller 1220, memory controller 1220 includes command (CMD) logic 1224, which represents logic or circuitry to generate commands to send to memory devices 1240. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 1240, memory controller 1220 can issue commands via I/O 1222 to cause memory device 1240 to execute the commands. In one example, controller 1250 of memory device 1240 receives and decodes command and address information received via I/O 1242 from memory controller 1220. Based on the received command and address information, controller 1250 can control the timing of operations of the logic and circuitry within memory device 1240 to execute the commands. Controller 1250 is responsible for compliance with standards or specifications within memory device 1240, such as timing and signaling requirements. Memory controller 1220 can implement compliance with standards or specifications by access scheduling and control.

Memory controller 1220 includes scheduler 1230, which represents logic or circuitry to generate and order transactions to send to memory device 1240. From one perspective, the primary function of memory controller 1220 could be said to schedule memory access and other transactions to memory device 1240. Such scheduling can include generating the transactions themselves to implement the requests for data by processor 1210 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 1220 typically includes logic such as scheduler 1230 to allow selection and ordering of transactions to improve performance of system 1200. Thus, memory controller 1220 can select which of the outstanding transactions should be sent to memory device 1240 in which order, which is typically achieved with logic much more complex that a simple first-in first-out algorithm. Memory controller 1220 manages the transmission of the transactions to memory device 1240, and manages the timing associated with the transaction. In one example, transactions have deterministic timing, which can be managed by memory controller 1220 and used in determining how to schedule the transactions with scheduler 1230.

In one example, memory controller 1220 includes refresh (REF) logic 1226. Refresh logic 1226 can be used for memory resources that are volatile and need to be refreshed to retain a deterministic state. In one example, refresh logic 1226 indicates a location for refresh, and a type of refresh to perform. Refresh logic 1226 can trigger self-refresh within memory device 1240, or execute external refreshes which can be referred to as auto refresh commands) by sending refresh commands, or a combination. In one example, controller 1250 within memory device 1240 includes refresh logic 1254 to apply refresh within memory device 1240. In one example, refresh logic 1254 generates internal operations to perform refresh in accordance with an external refresh received from memory controller 1220. Refresh logic 1254 can determine if a refresh is directed to memory device 1240, and what memory resources 1260 to refresh in response to the command.

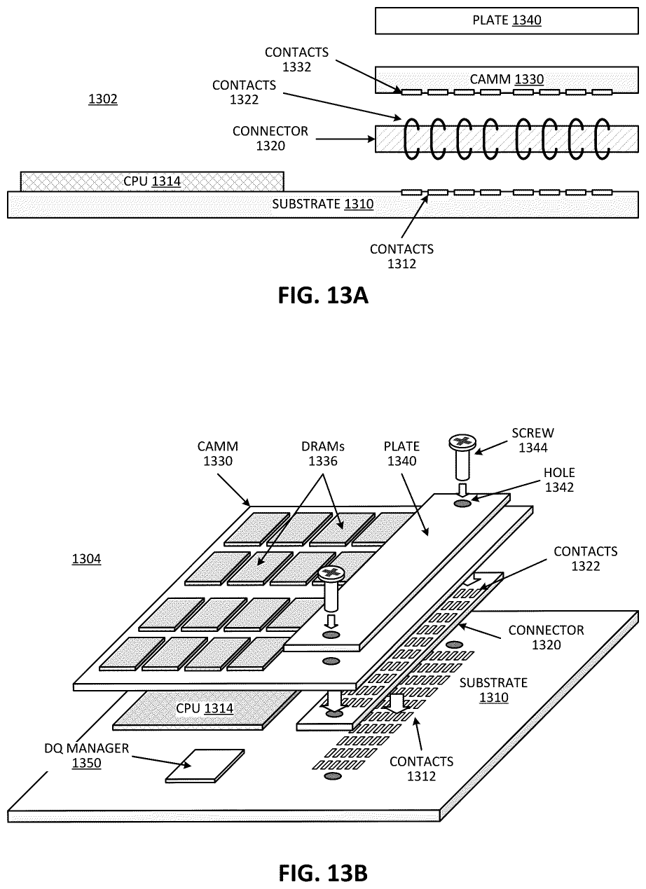

FIGS. 13A-13B are block diagrams of an example of a CAMM system in which DQ sparing can be implemented.

Referring to FIG. 13A, system 1000 includes a memory stack architecture monitored by a memory fault tracker that can perform mirroring. System 1302 is an example of a system in accordance with an example of system 100, an example of system 202, system 300, system 400, or system 1000.

Substrate 1310 illustrates an SOC package substrate or a motherboard or system board. Substrate 1310 includes contacts 1312, which represent contacts for connecting with memory. CPU 1314 represents a processor or central processing unit (CPU) chip or graphics processing unit (GPU) chip to be disposed on substrate 1310. CPU 1314 performs the computational operations in system 1302. In one example, CPU 1314 includes multiple cores (not specifically shown), which can generate operations that request data to be read from and written to memory. CPU 1314 can include a memory controller to manage access to the memory devices.

Compression-attached memory module (CAMM) 1330 represents a module with memory devices, which are not specifically illustrated in system 1302. Substrate 1310 couples to CAMM 1330 and its memory devices through compression mount technology (CMT) connector 1320. Connector 1320 includes contacts 1322, which are compression-based contacts. The compression-based contacts are compressible pins or devices whose shape compresses with the application of pressure on connector 1320. In one example, contacts 1322 represent C-shaped pins as illustrated. In one example, contacts 1322 represent another compressible pin shape, such as a spring-shape, an S-shape, or pins having other shapes that can be compressed.

CAMM 1330 includes contacts 1332 on a side of the CAMM board that interfaces with connector 1320. Contacts 1332 connect to memory devices on the CAMM board. Plate 1340 represents a plate or housing that provides structure to apply pressure to compress contacts 1322 of connector 1320.

Referring to FIG. 13B, system 1304 is a perspective view of a system in accordance with system 1302. System 1304 illustrates DQ manager 1350, which is not specifically illustrated in system 1302. DQ manager 1350 represents a controller that manages DQ sparing when a faulty DQ is detected. The DQ sparing can be performed in accordance with any example described. The DQ sparing includes repurposing freed ECC bits for the data of the spared DQ. A DQ remapper can remap the data to return to the program that triggered a read, or remap the data from a program that triggered a write.

CAMM 1330 is illustrated with memory chips or memory dies, identified as DRAMs 1336 on one or both faces of the PCB of CAMM 1330. DRAMs 1336 are coupled with conductive contacts via conductive traces in or on the PCB, which couples with contacts 1332, which in turn couple with contacts 1322 of connector 1320.

System 1304 illustrates holes 1342 in plate 1340 to receive fasteners, represented by screws 1344. There are corresponding holes through CAMM 1330, connector 1320, and in substrate 1310. Screws 1344 can compressibly attach the CAMM 1330 to substrate 1310 via connector 1320.

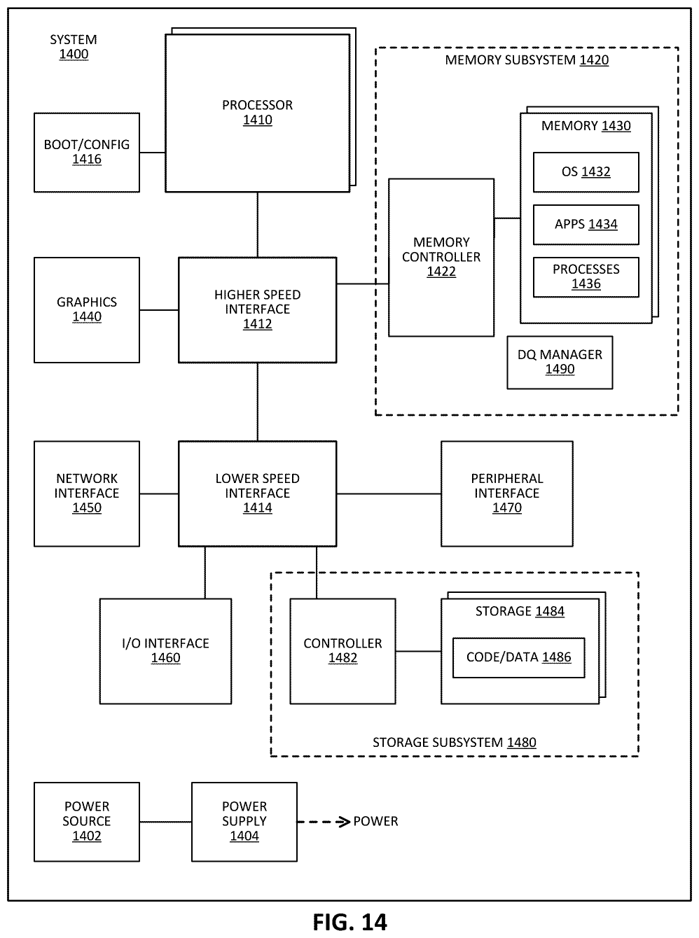

FIG. 14 is a block diagram of an example of a computing system in which DQ sparing can be implemented. System 1400 represents a computing device in accordance with any example herein, and can be a laptop computer, a desktop computer, a tablet computer, a server, a gaming or entertainment control system, embedded computing device, or other electronic device.

System 1400 is an example of a system in accordance with an example of system 100, an example of system 202, system 300, system 400, or system 1000. In one example, system 1400 includes DQ manager 1490, which represents a controller that manages DQ sparing when a faulty DQ is detected. The DQ sparing can be performed in accordance with any example described. The DQ sparing includes repurposing freed ECC bits for the data of the spared DQ. A DQ remapper can remap the data to return to the program that triggered a read, or remap the data from a program that triggered a write.

System 1400 includes processor 1410 can include any type of microprocessor, central processing unit (CPU), graphics processing unit (GPU), processing core, or other processing hardware, or a combination, to provide processing or execution of instructions for system 1400. Processor 1410 can be a host processor device. Processor 1410 controls the overall operation of system 1400, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1400 includes boot/config 1416, which represents storage to store boot code (e.g., basic input/output system (BIOS)), configuration settings, security hardware (e.g., trusted platform module (TPM)), or other system level hardware that operates outside of a host OS. Boot/config 1416 can include a nonvolatile storage device, such as read-only memory (ROM), flash memory, or other memory devices.

In one example, system 1400 includes interface 1412 coupled to processor 1410, which can represent a higher speed interface or a high throughput interface for system components that need higher bandwidth connections, such as memory subsystem 1420 or graphics interface components 1440. Interface 1412 represents an interface circuit, which can be a standalone component or integrated onto a processor die. Interface 1412 can be integrated as a circuit onto the processor die or integrated as a component on a system on a chip. Where present, graphics interface 1440 interfaces to graphics components for providing a visual display to a user of system 1400. Graphics interface 1440 can be a standalone component or integrated onto the processor die or system on a chip. In one example, graphics interface 1440 can drive a high definition (HD) display or ultra high definition (UHD) display that provides an output to a user. In one example, the display can include a touchscreen display. In one example, graphics interface 1440 generates a display based on data stored in memory 1430 or based on operations executed by processor 1410 or both.

Memory subsystem 1420 represents the main memory of system 1400, and provides storage for code to be executed by processor 1410, or data values to be used in executing a routine. Memory subsystem 1420 can include one or more varieties of random-access memory (RAM) such as DRAM, 3DXP (three-dimensional crosspoint), or other memory devices, or a combination of such devices. Memory 1430 stores and hosts, among other things, operating system (OS) 1432 to provide a software platform for execution of instructions in system 1400. Additionally, applications 1434 can execute on the software platform of OS 1432 from memory 1430. Applications 1434 represent programs that have their own operational logic to perform execution of one or more functions. Processes 1436 represent agents or routines that provide auxiliary functions to OS 1432 or one or more applications 1434 or a combination. OS 1432, applications 1434, and processes 1436 provide software logic to provide functions for system 1400. In one example, memory subsystem 1420 includes memory controller 1422, which is a memory controller to generate and issue commands to memory 1430. It will be understood that memory controller 1422 could be a physical part of processor 1410 or a physical part of interface 1412. For example, memory controller 1422 can be an integrated memory controller, integrated onto a circuit with processor 1410, such as integrated onto the processor die or a system on a chip.

While not specifically illustrated, it will be understood that system 1400 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1400 includes interface 1414, which can be coupled to interface 1412. Interface 1414 can be a lower speed interface than interface 1412. In one example, interface 1414 represents an interface circuit, which can include standalone components and integrated circuitry. In one example, multiple user interface components or peripheral components, or both, couple to interface 1414. Network interface 1450 provides system 1400 the ability to communicate with remote devices (e.g., servers or other computing devices) over one or more networks. Network interface 1450 can include an Ethernet adapter, wireless interconnection components, cellular network interconnection components, USB (universal serial bus), or other wired or wireless standards-based or proprietary interfaces. Network interface 1450 can exchange data with a remote device, which can include sending data stored in memory or receiving data to be stored in memory.

In one example, system 1400 includes one or more input/output (I/O) interface(s) 1460. I/O interface 1460 can include one or more interface components through which a user interacts with system 1400 (e.g., audio, alphanumeric, tactile/touch, or other interfacing). Peripheral interface 1470 can include any hardware interface not specifically mentioned above. Peripherals refer generally to devices that connect dependently to system 1400. A dependent connection is one where system 1400 provides the software platform or hardware platform or both on which operation executes, and with which a user interacts.

In one example, system 1400 includes storage subsystem 1480 to store data in a nonvolatile manner. In one example, in certain system implementations, at least certain components of storage 1480 can overlap with components of memory subsystem 1420. Storage subsystem 1480 includes storage device(s) 1484, which can be or include any conventional medium for storing large amounts of data in a nonvolatile manner, such as one or more magnetic, solid state, NAND, 3DXP, or optical based disks, or a combination. Storage 1484 holds code or instructions and data 1486 in a persistent state (i.e., the value is retained despite interruption of power to system 1400). Storage 1484 can be generically considered to be a “memory,” although memory 1430 is typically the executing or operating memory to provide instructions to processor 1410. Whereas storage 1484 is nonvolatile, memory 1430 can include volatile memory (i.e., the value or state of the data is indeterminate if power is interrupted to system 1400). In one example, storage subsystem 1480 includes controller 1482 to interface with storage 1484. In one example controller 1482 is a physical part of interface 1414 or processor 1410, or can include circuits or logic in both processor 1410 and interface 1414.

Power source 1402 provides power to the components of system 1400. More specifically, power source 1402 typically interfaces to one or multiple power supplies 1404 in system 1400 to provide power to the components of system 1400. In one example, power supply 1404 includes an AC to DC (alternating current to direct current) adapter to plug into a wall outlet. Such AC power can be renewable energy (e.g., solar power) power source 1402. In one example, power source 1402 includes a DC power source, such as an external AC to DC converter. In one example, power source 1402 or power supply 1404 includes wireless charging hardware to charge via proximity to a charging field. In one example, power source 1402 can include an internal battery or fuel cell source.

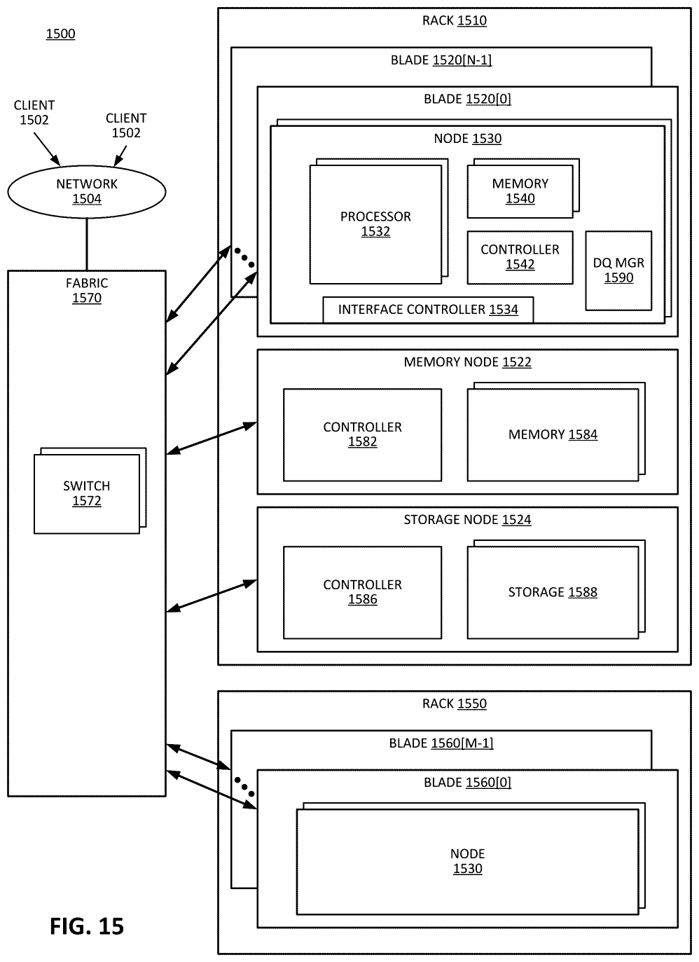

FIG. 15 is a block diagram of an example of a multi-node network in which DQ sparing can be implemented. In one example, system 1500 represents a data center. In one example, system 1500 represents a server farm. In one example, system 1500 represents a data cloud or a processing cloud.

Nodes 1530 of system 1500 represent a system in accordance with an example of system 100, an example of system 202, system 300, system 400, or system 1000. In one example, node 1530 includes DQ manager 1590, which represents a controller that manages DQ sparing when a faulty DQ is detected. The DQ sparing can be performed in accordance with any example described. The DQ sparing includes repurposing freed ECC bits for the data of the spared DQ. A DQ remapper can remap the data to return to the program that triggered a read, or remap the data from a program that triggered a write.

One or more clients 1502 make requests over network 1504 to system 1500. Network 1504 represents one or more local networks, or wide area networks, or a combination. Clients 1502 can be human or machine clients, which generate requests for the execution of operations by system 1500. System 1500 executes applications or data computation tasks requested by clients 1502.

In one example, system 1500 includes one or more racks, which represent structural and interconnect resources to house and interconnect multiple computation nodes. In one example, rack 1510 includes multiple nodes 1530. In one example, rack 1510 hosts multiple blade components, blade 1520[0], . . . , blade 1520[N−1], collectively blades 1520. Hosting refers to providing power, structural or mechanical support, and interconnection. Blades 1520 can refer to computing resources on printed circuit boards (PCBs), where a PCB houses the hardware components for one or more nodes 1530. In one example, blades 1520 do not include a chassis or housing or other “box” other than that provided by rack 1510. In one example, blades 1520 include housing with exposed connector to connect into rack 1510. In one example, system 1500 does not include rack 1510, and each blade 1520 includes a chassis or housing that can stack or otherwise reside in close proximity to other blades and allow interconnection of nodes 1530.

System 1500 includes fabric 1570, which represents one or more interconnectors for nodes 1530. In one example, fabric 1570 includes multiple switches 1572 or routers or other hardware to route signals among nodes 1530. Additionally, fabric 1570 can couple system 1500 to network 1504 for access by clients 1502. In addition to routing equipment, fabric 1570 can be considered to include the cables or ports or other hardware equipment to couple nodes 1530 together. In one example, fabric 1570 has one or more associated protocols to manage the routing of signals through system 1500. In one example, the protocol or protocols is at least partly dependent on the hardware equipment used in system 1500.

As illustrated, rack 1510 includes N blades 1520. In one example, in addition to rack 1510, system 1500 includes rack 1550. As illustrated, rack 1550 includes M blade components, blade 1560[0], . . . , blade 1560[M−1], collectively blades 1560. M is not necessarily the same as N; thus, it will be understood that various different hardware equipment components could be used, and coupled together into system 1500 over fabric 1570. Blades 1560 can be the same or similar to blades 1520. Nodes 1530 can be any type of node and are not necessarily all the same type of node. System 1500 is not limited to being homogenous, nor is it limited to not being homogenous.

The nodes in system 1500 can include compute nodes, memory nodes, storage nodes, accelerator nodes, or other nodes. Rack 1510 is represented with memory node 1522 and storage node 1524, which represent shared system memory resources, and shared persistent storage, respectively. One or more nodes of rack 1550 can be a memory node or a storage node.

Nodes 1530 represent examples of compute nodes. For simplicity, only the compute node in blade 1520[0] is illustrated in detail. However, other nodes in system 1500 can be the same or similar. At least some nodes 1530 are computation nodes, with processor (proc) 1532 and memory 1540. A computation node refers to a node with processing resources (e.g., one or more processors) that executes an operating system and can receive and process one or more tasks. In one example, at least some nodes 1530 are server nodes with a server as processing resources represented by processor 1532 and memory 1540.

Memory node 1522 represents an example of a memory node, with system memory external to the compute nodes. Memory nodes can include controller 1582, which represents a processor on the node to manage access to the memory. The memory nodes include memory 1584 as memory resources to be shared among multiple compute nodes.

Storage node 1524 represents an example of a storage server, which refers to a node with more storage resources than a computation node, and rather than having processors for the execution of tasks, a storage server includes processing resources to manage access to the storage nodes within the storage server. Storage nodes can include controller 1586 to manage access to the storage 1588 of the storage node.

In one example, node 1530 includes interface controller 1534, which represents logic to control access by node 1530 to fabric 1570. The logic can include hardware resources to interconnect to the physical interconnection hardware. The logic can include software or firmware logic to manage the interconnection. In one example, interface controller 1534 is or includes a host fabric interface, which can be a fabric interface in accordance with any example described herein. The interface controllers for memory node 1522 and storage node 1524 are not explicitly shown.

Processor 1532 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1540 can be or include memory devices represented by memory 1540 and a memory controller represented by controller 1542.

In general with respect to the descriptions herein, in one aspect, a memory controller includes: a hardware interface to a data bus, the data bus to couple to multiple data dynamic random access memory (DRAM) devices and at least one error correction code (ECC) DRAM device; and an error manager to detect a failure of a data signal (DQ) of one of the multiple data DRAM devices when coupled to the data bus, dynamically switch ECC mode on-the-fly, map out data bits of the DQ and remap ECC bits of the at least one ECC DRAM device to the mapped out data bits of the DQ.

In one example of the memory controller, the data bus has at least two ECC DRAM devices. In accordance with any prior example of the memory controller, in one example, the error manager is to remap ECC bits of only one DQ of an ECC device to the mapped out DQ. In accordance with any prior example of the memory controller, in one example, the error manager is to remap ECC bits of multiple DQs of an ECC device to the mapped out DQ. In accordance with any prior example of the memory controller, in one example, the error manager is to dynamically switch ECC mode from a 10×4 128-bit ECC mode to a 10×4 96-bit ECC mode. In accordance with any prior example of the memory controller, in one example, the error manager is to subsequently dynamically switch ECC mode from the 10×4 96-bit ECC mode to a 9×4 64-bit ECC mode. In accordance with any prior example of the memory controller, in one example, the error manager is to dynamically switch ECC mode from a 10×4 128-bit ECC mode to a 9×4 64-bit ECC mode. In accordance with any prior example of the memory controller, in one example, the error manager is to refresh a bank that contained the mapped out data bits of the DQ, wherein the memory controller is to hold read and write requests to the bank until all cachelines of the bank are refreshed. In accordance with any prior example of the memory controller, in one example, the error manager is to refresh a bank that contained the mapped out data bits of the DQ, wherein the error manager includes an address checker with a register to track refresh of cachelines of the bank during bank idle time.

In general with respect to the descriptions herein, in one aspect, a system for managing memory errors comprising: multiple data dynamic random access memory (DRAM) devices coupled to a data bus; an error correct code (ECC) DRAM device coupled to the data bus; and a data signal (DQ) manager to detect a failure of a DQ of one of the multiple data DRAM devices, dynamically switch ECC mode on-the-fly, map out data bits of the DQ, and remap ECC bits of the ECC DRAM device to the mapped out data bits of the DQ.

In accordance with an example of the system, the DQ manager comprises a circuit of a memory controller coupled to the data bus. In accordance with any prior example of the system, in one example, the DQ manager comprises a circuit of a controller disposed on a substrate, separate from a memory controller coupled to the data bus. In accordance with any prior example of the system, in one example, the ECC DRAM device comprises a first ECC DRAM device and further comprising a second ECC DRAM device. In accordance with any prior example of the system, in one example, the DQ manager is to remap ECC bits of only one ECC device to the mapped out DQ. In accordance with any prior example of the system, in one example, the DQ manager is to remap ECC bits of multiple ECC devices to the mapped out DQ. In accordance with any prior example of the system, in one example, the DQ manager is to dynamically switch ECC mode from a 10×4 128-bit ECC mode to a 10×4 96-bit ECC mode. In accordance with any prior example of the system, in one example, the DQ manager is to dynamically switch ECC mode from a first ECC mode to a 9×4 64-bit ECC mode. In accordance with any prior example of the system, in one example, the system includes a memory controller coupled to the data bus, wherein the DQ manager is to refresh a bank that contained the mapped out data bits of the DQ wherein the memory controller is to hold read and write requests to the bank until all cachelines of the bank are refreshed. In accordance with any prior example of the system, in one example, the DQ manager is to refresh a bank that contained the mapped out data bits of the DQ wherein the DQ manager includes an address checker with a register to track refresh of cachelines of the bank during bank idle time. In accordance with any prior example of the system, in one example, the system includes one or more of: a display communicatively coupled to a central processing unit (CPU); a network interface communicatively coupled to a host processor; or a battery to power the system.

In one aspect, a method includes: detecting a failure of a data signal (DQ) of a data bus coupled to multiple data dynamic random access memory (DRAM) devices and at least one error correction code (ECC) DRAM device; dynamically switching ECC mode on-the-fly; mapping out data bits of the DQ; and remapping ECC bits of the at least one ECC DRAM device to the mapped out data bits of the DQ.

In accordance with an example of the method, the data bus has at least two ECC DRAM devices. In accordance with any prior example of the method, in one example, remapping the ECC bits comprises remapping ECC bits of only one DQ of an ECC device to the mapped out DQ. In accordance with any prior example of the method, in one example, remapping the ECC bits comprises remapping ECC bits of multiple DQs of an ECC device to the mapped out DQ. In accordance with any prior example of the method, in one example, dynamically switching ECC mode comprises dynamically switching ECC mode from a 10×4 128-bit ECC mode to a 10×4 96-bit ECC mode. In accordance with any prior example of the method, in one example, dynamically switching ECC mode comprises subsequently, dynamically switching ECC mode from the 10×4 96-bit ECC mode to a 9×4 64-bit ECC mode. In accordance with any prior example of the method, in one example, dynamically switching ECC mode comprises dynamically switching ECC mode from a 10×4 128-bit ECC mode to a 9×4 64-bit ECC mode. In accordance with any prior example of the method, in one example, the method further includes refreshing a bank that contained the mapped out data bits of the DQ including holding read and write requests to the bank until all cachelines of the bank are refreshed. In accordance with any prior example of the method, in one example, the method further includes refreshing a bank that contained the mapped out data bits of the DQ, and tracking refresh of cachelines of the bank during bank idle time with an address checker having a register to track refresh.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory controller comprising:
a hardware interface to a data bus, the data bus to couple to multiple data dynamic random access memory (DRAM) devices and at least one error correction code (ECC) DRAM device; and
an error manager to detect a failure of a data signal (DQ) of one of the multiple data DRAM devices when coupled to the data bus, dynamically switch ECC mode on-the-fly, map out data bits of the DQ, and remap ECC bits of the at least one ECC DRAM device to the mapped out data bits of the DQ.

2. The memory controller of claim 1, wherein the data is to couple to at least two ECC DRAM devices.

3. The memory controller of claim 2, wherein the error manager is to remap ECC bits of only one DQ of an ECC device to the mapped out DQ.

4. The memory controller of claim 2, wherein the error manager is to remap ECC bits of multiple DQs of an ECC device to the mapped out DQ.

5. The memory controller of claim 2, wherein the error manager is to dynamically switch ECC mode from a 10×4 128-bit ECC mode to a 10×4 96-bit ECC mode.

6. The memory controller of claim 5, wherein the error manager is to subsequently dynamically switch ECC mode from the 10×4 96-bit ECC mode to a 9×4 64-bit ECC mode.

7. The memory controller of claim 2, wherein the error manager is to dynamically switch ECC mode from a 10×4 128-bit ECC mode to a 9×4 64-bit ECC mode.

8. The memory controller of claim 1, wherein the error manager is to refresh a bank that contained the mapped out data bits of the DQ wherein the memory controller is to hold read and write requests to the bank until all cachelines of the bank are refreshed.

9. The memory controller of claim 1, wherein the error manager is to refresh a bank that contained the mapped out data bits of the DQ wherein the error manager includes an address checker with a register to track refresh of cachelines of the bank during bank idle time.

10. A system for managing memory errors comprising:
multiple data dynamic random access memory (DRAM) devices coupled to a data bus;
an error correct code (ECC) DRAM device coupled to the data bus; and
a data signal (DQ) manager to detect a failure of a DQ of one of the multiple data DRAM devices, dynamically switch ECC mode on-the-fly, map out data bits of the DQ, and remap ECC bits of the ECC DRAM device to the mapped out data bits of the DQ.

11. The system of claim 10, wherein the DQ manager comprises a circuit of a memory controller coupled to the data bus.

12. The system of claim 10, wherein the DQ manager comprises a circuit of a controller disposed on a substrate, separate from a memory controller coupled to the data bus.

13. The system of claim 10, wherein the ECC DRAM device comprises a first ECC DRAM device and further comprising a second ECC DRAM device.

14. The system of claim 13, wherein the DQ manager is to remap ECC bits of only one ECC device to the mapped out DQ.

15. The system of claim 13, wherein the DQ manager is to remap ECC bits of multiple ECC devices to the mapped out DQ.

16. The system of claim 13, wherein the DQ manager is to dynamically switch ECC mode from a 10×4 128-bit ECC mode to a 10×4 96-bit ECC mode.

17. The system of claim 13, wherein the DQ manager is to dynamically switch ECC mode from a first ECC mode to a 9×4 64-bit ECC mode.

18. The system of claim 10, further comprising a memory controller coupled to the data bus, wherein the DQ manager is to refresh a bank that contained the mapped out data bits of the DQ, wherein the memory controller is to hold read and write requests to the bank until all cachelines of the bank are refreshed.

19. The system of claim 10, wherein the DQ manager is to refresh a bank that contained the mapped out data bits of the DQ wherein the DQ manager includes an address checker with a register to track refresh of cachelines of the bank during bank idle time.

20. The system of claim 10, further comprising one or more of:
a display communicatively coupled to a central processing unit (CPU);
a network interface communicatively coupled to a host processor; or
a battery to power the system.
